(19) United States
(12) Patent Application Publication
(10) Pub. No.: US 2026/0190652 A1
(43) Pub. Date: Jul. 2, 2026

(54) DISPLAY DEVICE

(71) Applicant: LG Display Co., Ltd., Seoul (KR)

(72) Inventors: Jungeun LEE, Paju-si (KR); HwanKeon LEE, Paju-si (KR); Jeongbeom LEE, Paju-si (KR); Junhyeok LEE, Paju-si (KR)

(73) Assignee: LG Display Co., Ltd., Seoul (KR)

(21) Appl. No.: 19/224,393

(22) Filed: May 30, 2025

(30) Foreign Application Priority Data
Dec. 31, 2024 (KR) 10-2024-0202205

(51) Int. Cl. H10K 59/123; H10H 29/39; H10H 29/85; H10H 29/852; H10K 59/38; H10K 59/40; H10K 59/80

(52) U.S. Cl. CPC H10K 59/123; H10H 29/39; H10H 29/8517; H10H 29/852; H10K 59/38; H10K 59/40; H10K 59/873

(57) ABSTRACT

Discussed is a display device capable of mitigating rainbow mura and reflection visibility. The display device includes a substrate having at least one subpixel, a thin film transistor disposed on the substrate, a first planarization layer positioned on the thin film transistor, a relay electrode positioned on the first planarization layer and electrically connected to the thin film transistor through a contact hole of the first planarization layer, a second planarization layer positioned on the first planarization layer and disposed to cover the relay electrode, and a light emitting element positioned on the second planarization layer and electrically connected to the relay electrode through a contact hole of the second planarization layer, and making an upper surface of the second planarization layer a flat plane and parallel to an upper surface of the substrate.

### CROSS-REFERENCE TO RELATED APPLICATION

This application claims priority to Korean Patent Application No. 10-2024-0202205, filed in the Republic of Korea on Dec. 31, 2024, which is hereby expressly incorporated by reference for all purposes as if fully set forth herein into the present application.

### BACKGROUND

### Field

Embodiments of the present disclosure relate to a display device.

### Discussion of the Related Art

With development in technology and advent of information society, demand for display devices that display images containing information is increasing, and various types of display devices are utilized to efficiently provide such information. Such display devices include liquid crystal display devices, light emitting display devices, etc.

A light emitting display device includes a light emitting element that emits light in a display area of the display device, and the light emitting element includes an anode, a light emitting layer, and a cathode among other elements. The light emitting element should be formed on a flat surface to ensure consistent and uniform emission of light from the light emitting display device.

Various components, including lines and driving elements, are formed beneath the light emitting element to supply signals and voltages, resulting in a non-flat, stepped surface that can hinder consistent and uniform emission of the light.

A planarization layer formed of an organic material can be disposed to allow the light emitting element to be stably disposed on a flat surface and to planarize a lower portion of the light emitting element to provide consistent and uniform emission of the light.

### BRIEF SUMMARY OF THE DISCLOSURE

Embodiments of the present disclosure can provide a display device that enhances the flatness of a pixel electrode by leveling the upper surface of a planarization layer formed beneath the pixel electrode.

Embodiments of the present disclosure can provide a display device capable of reducing or preventing the generation of foreign objects in the planarization layer and its contact hole by incorporating a planarization auxiliary layer in the planarization layer.

Embodiments of the present disclosure can provide a display device that enhances reflection visibility and mitigates rainbow mura by minimizing the occurrence of foreign objects during the formation of the planarization layer and contact holes.

Objects of embodiments of the present disclosure are not limited to those set forth herein, and other unmentioned objects would be apparent to one of ordinary skill in the art from the following description.

Embodiments of the present disclosure can provide a display device including a substrate including a subpixel, a thin film transistor disposed on the substrate, a first planarization layer positioned on the thin film transistor, a relay electrode positioned on the first planarization layer and electrically connected to the thin film transistor through a contact hole of the first planarization layer, a second planarization layer positioned on the first planarization layer and disposed to cover the relay electrode, and a light emitting element positioned on the second planarization layer and electrically connected to the relay electrode through a contact hole of the second planarization layer, wherein an upper surface of the second planarization layer is a flat plane and is parallel to an upper surface of the substrate.

Embodiments of the present disclosure can provide the display device further including a planarization auxiliary layer positioned on the first planarization layer and disposed to cover the relay electrode.

Embodiments of the present disclosure can provide the display device further including a planarization auxiliary layer positioned on the second planarization layer and disposed not to overlap the relay electrode.

According to embodiments of the present disclosure, there can be provided a display device that enhances the flatness of a pixel electrode by leveling the upper surface of a planarization layer formed beneath the pixel electrode.

According to embodiments of the present disclosure, there can be provided a display device capable of reducing or preventing the generation of foreign objects in the planarization layer and its contact hole by incorporating a planarization auxiliary layer in the planarization layer.

According to embodiments of the present disclosure, there can be provided a display device that enhances reflection visibility and mitigates rainbow mura by minimizing the occurrence of foreign objects during the formation of the planarization layer and contact holes.

According to embodiments of the present disclosure, there can be provided a display device capable of low-power consumption by mitigating rainbow mura and reflection visibility.

The effects of the present disclosure are not limited to the foregoing objects, and other effects will be apparent to one of ordinary skill in the art from the following detailed description.

### BRIEF DESCRIPTION OF THE DRAWINGS

The present disclosure will be more fully understood from the following detailed description and the accompanying drawings, which are provided for illustration only and are not intended to limit the present disclosure.

FIG. 1 is a view illustrating an example system configuration of a display device according to embodiments of the present disclosure;

FIG. 2 illustrates an example display panel according to an embodiment of the present disclosure;

FIG. 3 is an example cross-sectional view illustrating a subpixel area of a display device according to embodiments of the present disclosure;

FIG. 4 is another example cross-sectional view illustrating a subpixel area of a display device according to embodiments of the present disclosure;

FIG. 5 is another example cross-sectional view illustrating a subpixel area of a display device according to embodiments of the present disclosure;

FIGS. 6A to 6C are example views illustrating a contact hole area of a display device according to embodiments of the present disclosure;

FIGS. 7A and 7B are example cross-sectional views illustrating a contact hole area of a display device according to embodiments of the present disclosure;

FIGS. 8A to 8C are example views illustrating a process for manufacturing the display device illustrated in FIG. 3;

FIGS. 9A to 9E are other example views illustrating a process for manufacturing the display device illustrated in FIG. 3;

FIGS. 10A to 10C are example views illustrating a process for manufacturing the display device illustrated in FIG. 4;

FIGS. 11A to 11D are other example views illustrating a process for manufacturing the display device illustrated in FIG. 4; and

FIGS. 12A to 12F are example views illustrating a process for manufacturing the display device illustrated in FIG. 5.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure are described in detail with reference to the accompanying drawings.

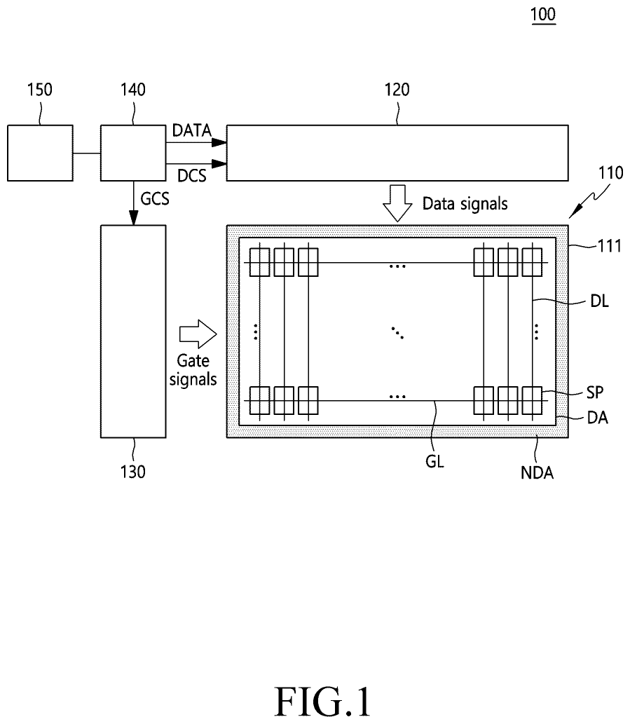

FIG. 1 is a view illustrating a system configuration of a display device 100 according to embodiments of the present disclosure. All the components of the display device 100 according to all embodiments are operationally coupled and configured.

Referring to FIG. 1, a display device 100 according to embodiments of the present disclosure can include a display panel 110 and display driving circuits, as components for displaying images. The display driving circuits are circuits for driving the display panel 110 and can include a data driving circuit 120, a gate driving circuit 130, and a controller 140.

The display panel 110 can include a substrate 111 and a plurality of subpixels SP disposed on the substrate 111.

The substrate 111 can include a display area DA capable of displaying an image and a non-display area NDA positioned outside the display area DA.

The display area DA can also be referred to as an active area, and a plurality of subpixels SP for displaying an image can be disposed in the display area DA. The non-display area NDA can also be referred to as a non-active area and can include a pad area.

In the display panel 110 according to embodiments of the present disclosure, the non-display area NDA can be very small relative to the display area DA. In the present disclosure, the non-display area NDA is also referred to as a “bezel.” For example, the non-display area NDA can include a first non-display area positioned outside in the first direction from the display area DA, a second non-display area positioned outside in the second direction from the display area DA, a third non-display area positioned outside in a direction opposite to the first direction from the display area DA, and a fourth non-display area positioned outside in a direction opposite to the second direction from the display area DA.

The first non-display area can include a pad area to which a driving circuit is connected or bonded. The second to fourth non-display areas can have a very small size.

As another example, the boundary area between the display area DA and the non-display area NDA can be bent so that the non-display area NDA can be positioned under the display area. In this case, no or little change can be made to the non-display area NDA shown to the user when the user views the display area 100 from the front. For example, the first non-display area can include a bending area. As the bending area is bent, the first non-display area can be not visible from the front.

Various types of signal lines for driving a plurality of subpixels SP can be disposed on the substrate 111 of the display panel 110.

The display device 100 according to embodiments of the present disclosure can be a liquid crystal display device or a self-emission display device in which the display panel 110 emits light by itself. When the display device 100 according to the embodiments of the present disclosure is a self-emission display device, each of the plurality of subpixels SP can include a light emitting element.

For example, the display device 100 according to embodiments of the present disclosure can be an organic light emitting display in which the light emitting element is implemented as an organic light emitting diode (OLED). As another example, the display device 100 according to embodiments of the present disclosure can be an inorganic light emitting display device in which the light emitting element is implemented as an inorganic material-based light emitting diode. As another example, the display device 100 according to embodiments of the present disclosure can be a quantum dot display device in which the light emitting element is implemented as a quantum dot which is self-emission semiconductor crystal.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors.

For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed to extend in the first direction. Each of the plurality of gate lines GL can be disposed to extend in the second direction. The first direction can be a column direction, and the second direction can be a row direction. The first direction can be the row direction, and the second direction can be the column direction. For convenience of description, in the following examples, the first direction is the column direction, and the second direction is the row direction. Thus, described below is an example in which each of the plurality of data lines DL is disposed in the column direction, and each of the plurality of gate lines GL is disposed in the row direction, but embodiments of the present disclosure are not limited thereto.

The data driving circuit 120 is a circuit for driving the plurality of data lines DL, and can output data signals to the plurality of data lines DL.

The data driving circuit 120 can receive digital image data DATA from the controller 140 and can convert the received image data DATA into analog data signals and output them to the plurality of data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but embodiments of the present disclosure are not limited thereto.

The data driving circuit 120 can be connected to one side (e.g., an upper or lower side) of the display panel 110. In contrast, depending on the driving scheme or the panel design scheme, data driving circuits 120 can be connected with both the sides (e.g., both the upper and lower sides) of the display panel 110, or two or more of the four sides of the display panel 110.

The data driving circuit 120 can be connected outside the display area DA of the display panel 110, but as another example, the data driving circuit 120 can be disposed in the display area DA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the present disclosure, the gate driving circuit 130 can be embedded, in a gate in panel (GIP) type, in the display panel 110. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-active area NDA of the display panel 110.

As another example, the gate driving circuit 130 can be disposed in the display area DA of the display panel 110. In this case, for example, the gate driving circuit 130 can be disposed in a first partial area in the display area DA (e.g., a left area or a right area in the display area DA). As another example, the gate driving circuit 130 can be disposed in a first partial area in the display area DA (e.g., a left area or right area in the display area DA) and a second partial area (e.g., a right area or left area in the display area DA).

In the present disclosure, the gate driving circuit 130 embedded in the display panel 110 in a gate-in-panel type can also be referred to as a “gate-in-panel circuit.”

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from the host system 150 and supply image data DATA to the data driving circuit 120 based on the input image data.

The controller 140 can be implemented as a separate component from the data driving circuit 120, or the controller 140 and the data driving circuit 120 can be integrated into an integrated circuit (IC).

The controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit.

The controller 140 can transmit/receive signals to/from the data driving circuit 120 according to one or more predetermined interfaces. The interface can include, e.g., a low voltage differential signaling (LVDS) interface, an embedded clock point-point interface (EPI) interface, and a serial peripheral interface (SPI), but embodiments of the present disclosure are not limited thereto.

To provide a touch sensing function as well as an image display function, the display device 100 according to embodiments of the present disclosure can include a touch sensor and a touch sensing circuit that senses the touch sensor to detect whether a touch occurs by a touch object, such as a finger or pen, or the position of the touch.

The touch sensing circuit can include a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside the display panel 110 or can be present inside the display panel 110. When the touch panel, in the form of a touch panel, exists outside the display panel 110, the touch panel is referred to as an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device. The touch driving circuit and the data driving circuit can be implemented as separate devices or as a single device.

The display device 100 can further include a power supply circuit for supplying various types of power to the display driver integrated circuit and/or the touch sensing circuit.

The display device 100 according to embodiments of the present disclosure can be a mobile terminal, such as a smart phone or a tablet, or a monitor or television (TV) in various sizes but, without limited thereto, can be a display in various types and various sizes capable of displaying information or images.

The display device 100 according to embodiments of the present disclosure can further include an electronic device such as a camera (image sensor), a detection sensor, or the like. For example, the detection sensor can be a sensor that detects an object or a human body by receiving light such as infrared rays, ultrasonic waves, or ultraviolet rays.

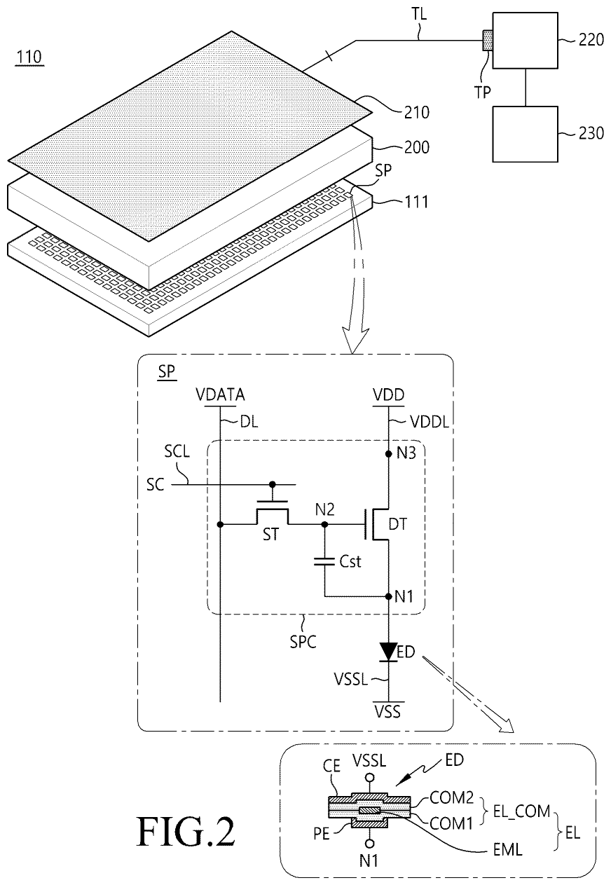

FIG. 2 illustrates a display panel 110 according to an embodiment of the present disclosure. What is identical or similar to those described with reference to FIG. 1 is omitted from the following description or briefly described below.

Referring to FIG. 2, the display panel 110 can include a substrate 111 disposed in a plurality of subpixels SP and an encapsulation layer 200 on the substrate 111. The encapsulation layer 200 can also be referred to as an encapsulation substrate or an encapsulation unit.

Referring to FIG. 2, when the display device 100 according to embodiments of the present disclosure is a self-luminous display device, each of the plurality of subpixels SP disposed on the substrate 111 can include a light emitting element ED and a subpixel circuit SPC for driving the light emitting element ED.

Referring to FIG. 2, the subpixel circuit SPC can include a plurality of transistors for driving the light emitting element ED and at least one capacitor. In the present disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scan transistor ST that is turned on or off according to the scan signal SC.

The driving transistor DT can supply a driving current to the light emitting element ED.

The scan transistor ST can be configured to control the electrical state of a corresponding node in the subpixel circuit SPC or to control the state or operation of the driving transistor DT.

The at least one capacitor can include a storage capacitor Cst for maintaining a constant voltage during a frame.

To drive the subpixel SP, a data signal VDATA as an image signal and a scan signal SC as a gate signal can be applied to the subpixel SP. Further, for driving the subpixel SP, a common driving voltage including the first common driving voltage VDD and the second common driving voltage VSS can be applied to the subpixel SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed in each subpixel SP, and the common electrode CE can be an electrode commonly disposed in all the subpixels SP. For example, the pixel electrode PE can be an anode, and the common electrode CE can be a cathode. As another example, the pixel electrode PE can be a cathode, and the common electrode CE can be an anode. For convenience of description, an example is described in which the pixel electrode PE is an anode, and the common electrode CE is a cathode.

When the light emitting element ED is an organic light emitting element, the intermediate layer EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be disposed commonly across a plurality of subpixel SP.

The light emitting layer EML can be disposed for each light emitting area, and the common intermediate layer EL_COM can be commonly disposed over the plurality of light emitting areas and the non-light emitting area.

For example, the first common intermediate layer COM1 can include a hole injection layer HIL and a hole transport layer HTL. The second common intermediate layer COM2 can include an electron transport layer ETL and an electron injection layer EIL.

The hole injection layer can inject holes from the pixel electrode PE to the hole transport layer, and the hole transport layer can transport holes to the light emitting layer EML. The electron injection layer can inject electrons from the common electrode CE to the electron transport layer, and the electron transport layer can transport electrons to the light emitting layer EML.

For example, the common electrode CE can be electrically connected to the second common driving voltage line VSSL. The second common driving voltage VSS can be applied to the common electrode CE through the second common driving voltage line VSSL. The pixel electrode PE can be electrically connected directly or indirectly (through another transistor) to the first node N1 of the driving transistor DT of each subpixel SP. In the present disclosure, “the second common driving voltage VSS” can also be referred to as a “base voltage”, and “the second common driving voltage line VSSL” can also be referred to as a “low-potential power voltage line” or “base voltage line”.

Each light emitting element ED can include portions where the pixel electrode PE, the light emitting layer EML in the intermediate layer LE, and the common electrode CE overlap. A predetermined light emitting area can be formed by each light emitting element ED. For example, the light emitting area of each light emitting element ED can include an overlapping area of the pixel electrode PE, the light emitting layer EML in the intermediate layer EL, and the common electrode CE.

For example, the light emitting element ED can be an organic light emitting diode (OLED), an inorganic light emitting diode (LED), or a quantum dot light emitting element. For example, when the light emitting element ED is an organic light emitting diode (OLED), the intermediate layer EL of the light emitting element ED can include an intermediate layer EL including an organic material.

The driving transistor DT can be a driving transistor for supplying a driving current to the light emitting element ED. The driving transistor DT can be connected between the first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A first common driving voltage VDD can be applied to the third node N3 from the first common driving voltage line VDDL.

In the driving transistor DT, the second node N2 can be a gate node, the first node N1 can be a source node or a drain node, and the third node N3 can be a drain node or a source node. Hereinafter, for convenience of description, an example is described in which in the driving transistor DT, the second node N2 can be a gate node (or gate electrode), the first node N1 can be a source node (or source electrode), and the third node N3 can be a drain node (or drain electrode), but embodiments of the present disclosure are not limited thereto.

The scan transistor ST included in the subpixel circuit SPC illustrated in FIG. 2 can be a switching transistor for transferring the data signal VDATA, which is an image signal, to the second node N2, which is the gate node of the driving transistor DT.

The scan transistor ST can be controlled to be turned on and off by the scan signal SC, which is a gate signal applied through the scan line SCL, which is a type of the gate line GL, to control electrical connection between the second node N2 of the driving transistor DT and the data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst can be an external capacitor designed to be outside the driving transistor DT, but not a parasite capacitor (e.g., Cgs or Cgd) which is an internal capacitor that can be present between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

When the display panel 110 has a top emission structure, at least a portion of the subpixel circuit SPC can overlap at least a portion of the light emitting element ED in a vertical direction. Accordingly, the area of the emission area can increase and the aperture ratio can increase.

When the display panel 110 has a bottom emission structure, the subpixel circuit SP can be not overlapping the light emitting element ED in the vertical direction.

As illustrated in FIG. 2, the subpixel circuit SPC can have a 2T (Transistor) 1C (Capacitor) structure including two transistors DT and ST and one capacitor Cst. In some cases, the subpixel circuit SPC can further include one or more transistors or can further include one or more capacitors.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7T1C structure including 7 transistors and 1 capacitor. Embodiments of the present disclosure are not limited thereto.

Depending on the structure of the subpixel circuit SPC, the type and number of gate lines or the gate signals supplied to the subpixel SP can vary. Further, the type and the number of common driving voltages supplied to the subpixel SP can vary depending on the structure of the subpixel circuit SPC.

Referring to FIG. 2, since the circuit elements (e.g., the light emitting element ED implemented as an organic light emitting diode (OLED) including an organic material) in each subpixel SP are vulnerable to external moisture or oxygen, the encapsulation layer 200 for preventing external moisture or oxygen from penetrating into the circuit elements (e.g., the light emitting element ED) can be disposed on the display panel 110.

The encapsulation layer 200 can be configured in various forms so that the light emitting elements ED do not contact moisture or oxygen. For example, the encapsulation layer 200 can be constituted of two or more layers in which organic layers and inorganic layers are alternately stacked, but embodiments of the present disclosure are not limited thereto.

Referring to FIG. 2, a display device 100 according to embodiments of the present disclosure can include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 can be embedded in the display panel 110. For example, the touch sensor layer 210 can be disposed on the encapsulation layer 200 in the display panel 110.

The display panel 110 can further include a plurality of touch pads TP electrically connected to the touch driving circuit 220 and a plurality of touch lines TL for electrically connecting the plurality of sensor electrodes included in the touch sensor layer 210 to the plurality of touch pads TP connected to the touch driving circuit 220.

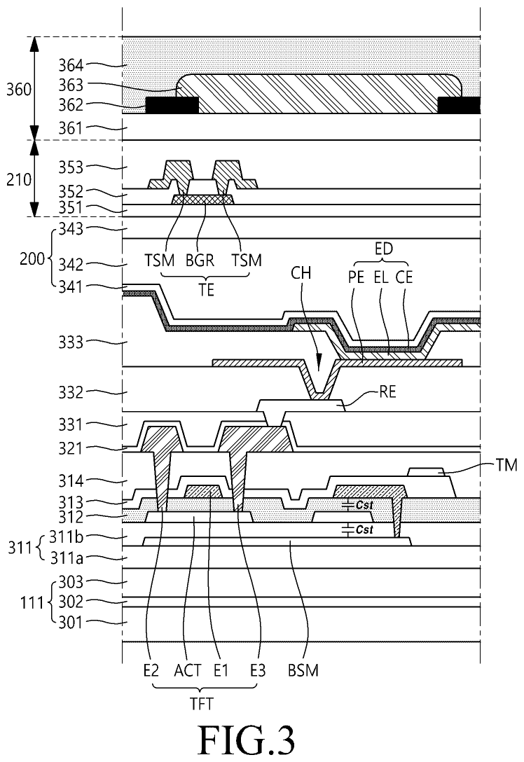

FIG. 3 is an example cross-sectional view illustrating a subpixel SP of a display device 100 according to embodiments of the present disclosure. What is identical or similar to those described in connection with FIGS. 1 and 2 can be omitted or briefly described below.

Referring to FIG. 3, the display panel 110 according to embodiments of the present disclosure can include a transistor forming unit, a light emitting element forming unit, and an encapsulation unit from a vertical structure perspective.

The substrate 111 can be a single layer or multiple layers. The substrate 111 can be formed of glass or a plastic material. When the substrate 111 includes multiple layers, the substrate 111 can include a first substrate 301, a substrate intermediate layer 302, and a second substrate 303. The substrate intermediate layer 302 can be positioned between the first substrate 301 and the second substrate 303. For example, each of the first substrate 301 and the second substrate 303 can be a polyimide (PI) layer. The substrate intermediate layer 302 can be an inorganic insulation layer. When an electric charge is charged to the first substrate 301 which is a polyimide layer, the substrate intermediate layer 302 can prevent the electric charge from affecting transistors disposed on the second substrate 303 through the second substrate 303 which is a polyimide layer.

Further, the substrate intermediate layer 302 can prevent a moisture component from penetrating upward through the first substrate 301. For example, the substrate intermediate layer 302 can be formed of a single layer of silicon nitride (SiNx) or silicon oxide (SiOx) or multiple layers thereof, or can be formed of a double layer of silicon dioxide (SiOx) and silicon nitride (SiNx), but is not limited thereto.

The transistor forming unit can include a substrate 111, various insulation layers 311, 312, 313, and 314 on the substrate 111, a transistor TFT, a storage capacitor Cst, and various electrodes or signal lines.

Referring to FIG. 3, the buffer layer 311 can be disposed on the substrate 111. The buffer layer 311 can be a single layer or multiple layers. When the buffer layer 311 includes multiple layers, the buffer layer 311 can include a multi-buffer layer 311a and an active buffer layer 311b.

The multi-buffer layer 311a can be an inorganic insulation layer. The multi-buffer layer 311a can block or delay diffusion of the moisture and/or oxygen penetrating the substrate 111. For example, the multi-buffer layer 311a can be formed of a single layer of silicon nitride (SiNx), silicon oxide (SiOx), or silicon oxynitride (SiOxNy), or multiple layers thereof, but is not limited thereto.

The active buffer layer 311b can be an inorganic insulation layer. The active buffer layer 311b can protect the active layer ACT of the transistor TFT and can perform the function of blocking or delaying various types of defects introduced from the substrate 111. For example, the active buffer layer 311b can be formed of a single layer of amorphous silicon (a-Si), silicon nitride (SiNx), or silicon oxide (SiOx), or multiple layers thereof, but is not limited thereto.

The shield metal BSM can be disposed between the multi-buffer layer 311a and the active buffer layer 311b. The shield metal BSM can constitute a display signal line or a portion of the storage capacitor Cst disposed in the subpixel SP.

The active layer ACT of the transistor TFT can be disposed on the buffer layer 311. For example, the active layer ACT can be disposed on the active buffer layer 311b. The active layer ACT can include a channel area where a channel is formed, a source connection area on one side of the channel area, and a drain connection area on the other side of the channel area. The active layer ACT can include a semiconductor material, but embodiments of the present disclosure are not limited thereto. For example, the active layer ACT can be formed of an oxide semiconductor, amorphous silicon, polysilicon, or low-temperature polysilicon (LTPS), but embodiments of the present disclosure are not limited thereto. The transistor TFT can be implemented as a p-channel transistor or an n-channel transistor, but embodiments of the present disclosure are not limited thereto. Further, the active layer ACT can be rendered conductive to constitute a portion of the display signal line or the storage capacitor Cst.

The gate insulation layer 312 can be disposed on the active layer ACT of the transistor TFT. The gate insulation layer 312 can be formed of a single layer of silicon nitride (SiNx) or silicon oxide (SiOx), or multiple layers thereof, but embodiments of the present disclosure are not limited thereto.

A gate metal layer can be disposed on the gate insulation layer 312. The gate metal layer GAT can constitute the first electrode E1 of the transistor TFT, or can constitute a portion of the display signal line or the storage capacitor Cst. The first electrode E1 of the transistor TFT can be the gate electrode E1 of the transistor TFT.

A first interlayer insulation layer 313 can be disposed on the gate electrode E1 of the transistor TFT. The first interlayer insulation layer 313 can be formed of a single layer of silicon nitride (SiNx) or silicon oxide (SiOx), or multiple layers thereof, but embodiments of the present disclosure are not limited thereto.

The auxiliary electrode layer TM can be disposed on the first interlayer insulation layer 313. The auxiliary electrode layer TM can be variously used to constitute a display signal line or a portion of the storage capacitor Cst.

A second interlayer insulation layer 314 can be disposed on the auxiliary electrode layer TM and the first interlayer insulation layer 313. The second interlayer insulation layer 314 can be formed of a single layer of silicon nitride (SiNx) or silicon oxide (SiOx), or multiple layers thereof, but embodiments of the present disclosure are not limited thereto.

A first source-drain metal layer can be disposed on the second interlayer insulation layer 314. The first source-drain metal layer can constitute the second electrode E2 and the third electrode E3 of the transistor TFT, or can constitute a display signal line or the like. The second electrode E2 of the transistor TFT can be a source electrode or a drain electrode, and the third electrode E3 of the transistor TFT can be a drain electrode or a source electrode. Hereinafter, for convenience of description, the second electrode E2 is referred to as the drain electrode E2, and the third electrode E3 is referred to as the source electrode E3. However, embodiments of the present disclosure are not limited thereto.

The source electrode E3 and the drain electrode E2 of the transistor TFT can be electrically connected to the source connection area and the drain connection area, respectively, of the active layer ACT through contact holes of the gate insulation layer 312, the first interlayer insulation layer 313, and the second interlayer insulation layer 314.

The protective layer 321 can be disposed on the first source-drain metal layer and the second interlayer insulation layer 314. The protective layer 321 can be formed of a single layer of silicon nitride (SiNx), silicon oxide (SiOx), or silicon oxynitride (SiOxNy), or multiple layers thereof, but the present disclosure is not limited thereto. Here, the protective layer 321 can be omitted.

At least one planarization layer can be disposed on the protective layer 321. In the example of FIG. 3, two planarization layers 331 and 332 are disposed on the protective layer 321, but embodiments of the present disclosure are not limited thereto. The planarization pattern can be an organic insulation layer capable of performing a planarization function.

Referring to FIG. 3, a first planarization layer 331 can be disposed on the source electrode E3 and the drain electrode E2 of the transistor TFT. The first planarization layer 331 can be disposed while covering the whole of the transistor TFT. The first planarization layer 331 can be an organic insulation layer for planarizing and protecting the upper portion of the transistor TFT. For example, the first planarization layer 331 can be formed of an insulating material such as acrylic resin, epoxy resin, phenolic resin, polyamide resin, polyimide resin, siloxane resin, etc. The first planarization layer 321 can alleviate the step formed by various components such as the transistor TFT, the storage capacitor Cst, and various signal lines disposed in each subpixel SP area.

Referring to FIG. 3, a second source-drain metal layer can be disposed on the first planarization layer 331. The second source-drain metal layer can constitute a relay electrode RE electrically connecting the third electrode E3 of the transistor TFT and the pixel electrode PE of the light emitting element ED, or can constitute a display signal line or the like. For example, the first source-drain metal layer or the second source-drain metal layer can constitute a data line DL and a gate line GL, which are display signal lines.

The relay electrode RE can be disposed on the first planarization layer 331. The relay electrode RE can be electrically connected to the source electrode E3 of the transistor TFT through the contact hole of the first planarization layer 331.

Referring to FIG. 3, a second planarization layer 332 can be disposed on the first planarization layer 331 and the relay electrode RE. For example, the second planarization layer 332 can be formed of an insulating material such as acrylic resin, epoxy resin, phenolic resin, polyamide resin, polyimide resin, siloxane resin, etc.

The second planarization layer 322 can completely remove the step formed by various components such as the transistor TFT, the storage capacitor Cst, the relay electrode RE, and various signal lines disposed in each subpixel SP area. In other words, the upper surface of the second planarization layer 332 can have a flat plane by the planarization process. The planarization process can include a chemical mechanical polishing (CMP) process. The upper surface of the second planarization layer 332 can have a flat plane by removing a stepped area through a chemical mechanical polishing (CMP) process.

The transmittance of the thin film surface of the second planarization layer 332 can be enhanced, and the surface component can be changed by a chemical mechanical polishing (CMP) process. For example, a thin film such as the second planarization layer 332 can include a siloxane resin. The siloxane resin thin film can be formed by coating a siloxane resin-based binder. In this case, at the beginning of the coating, the surface of the thin film can include carbon (C), oxygen (O), fluorine (F), nitrogen (N), sulfur (S), or the like at a high ratio. Thereafter, while performing the chemical mechanical polishing (CMP) process, changes in components of the thin film surface can occur and the thickness of the thin film can be decreased. As chemical mechanical polishing (CMP) is performed, some components can be removed from the thin film surface. For example, as chemical mechanical polishing (CMP) is performed, fluorine (F) and sulfur (S) components can be removed from the thin film surface, the proportion of carbon (C) can be relatively decreased compared to an internal bulk or internal portion of the thin film (such as the second planarization layer 332) that is away from the thin film surface, and the proportion of oxygen (O) can be relatively increased at the thin film surface. Meanwhile, as chemical mechanical polishing (CMP) is performed, the proportion of silicon (Si) on the surface of the thin film can be relatively increased. At the beginning of the coating, fluorine (F) or sulfur (S) components were positioned on the surface of the thin film covering silicon (SI) in the same amount or same ratio as those in the bulk or interior of the thin film, but as chemical mechanical polishing (CMP) is performed on the surface, fluorine (F) or sulfur (S) is removed and silicon (Si) can be positioned on the surface of the thin film. In other words, the fluorine (F) component can be decreased and the silicon (Si) component can be increased on the surface of the thin film by chemical mechanical polishing (CMP).

Meanwhile, as chemical mechanical polishing (CMP) is performed, the transmittance of the thin film including siloxane resin can be enhanced. Table 1 below shows changes in the thickness and transmittance of the thin film during chemical mechanical polishing (CMP).

TABLE 1

| | CMP | thin film | transmittance |
|---|---|---|---|
| | time | thickness | (%) (380 to |
| | (s) | (μm) | 780 nm Avg.) |
| comparative | 0 | 4.6 | 97.1 |
| example 1 | | | |
| embodiment 1 | 10 | 4.1 | 99.6 |
| embodiment 2 | 20 | 3.68 | 99.8 |
| embodiment 3 | 32 | 3.24 | 99.4 |

Referring to Table 1, it can be identified that the thickness of the thin film is decreased after the chemical mechanical polishing (CMP) process is performed, and the transmittance of the thin films of embodiments 1 to 3 is enhanced compared to that of the comparative example. In the case of embodiments 1 to 3, it can be identified that the transmittance according to the thickness of the thin film is similar. As a result of analyzing the surface components of the thin films according to the comparative example and embodiments 1 to 3, a high proportion of fluorine (F) was detected on the surface of the thin film in comparative example 1 but, in embodiments 1 to 3, fluorine (F) was removed on the surface of the thin film. In other words, by removing the fluorine (F) component on the surface of the thin film by a chemical mechanical polishing (CMP) process, the transmittance of the thin film can be enhanced.

An upper surface of the second planarization layer 332 facing the substrate 111 can be a flat plane. The upper surface of the second planarization layer 332 can be parallel to the upper surface of the substrate 111. In particular, the upper surface of the second planarization layer 332 overlapping the area where the relay electrode RE is disposed can have the same plane as the upper surface of the second planarization layer 332 in the area where the relay electrode RE is not disposed. In other words, the upper periphery of the contact hole CH provided in the second planarization layer 332 for connecting the relay electrode RE and the pixel electrode PE of the light emitting element ED and the upper surface of the second planarization layer 332 can have a flat plane. For example, a partial area of the second planarization layer 332 can have different properties from the other area of the second planarization layer 332. For example, a partial area of the second planarization layer 332 need not include fluorine F and sulfur S. For example, the upper peripheral area of the contact hole CH provided in the second planarization layer 332 need not include fluorine F and sulfur S compared to the other areas of the second planarization layer 332. Meanwhile, a partial area of the first planarization layer 331 need not include fluorine F and sulfur S, like the partial area of the second planarization layer 332. For example, the upper peripheral area of the contact hole CH provided in the first planarization layer 331 need not include fluorine F and sulfur S compared to the other areas of the first planarization layer 331. Therefore, the flatness of the second planarization layer 332 is enhanced, so that the lower step of the area where the pixel electrode PE of the light emitting element ED is disposed can be completely removed, thereby enhancing the flatness of the pixel electrode PE. As the flatness of the second planarization layer 332 and the pixel electrode PE is enhanced, reflection visibility and rainbow mura can be mitigated.

Referring to FIG. 3, the light emitting element forming unit can be disposed on the second planarization layer 332. The light emitting element ED can be formed on the second planarization layer 332. The light emitting element ED can include a pixel electrode PE, an intermediate layer EL, and a common electrode CE. The emission area of the light emitting element ED can be formed in an area in which the pixel electrode PE, the intermediate layer EL, and the common electrode CE overlap and contact each other.

The pixel electrode PE can be disposed on the second planarization layer 332. The pixel electrode PE can be electrically connected to the relay electrode RE through the contact hole CH of the second planarization layer 332.

A bank 333 can be disposed on the pixel electrode PE. The opening (or open portion) of the bank 333 can expose a portion of the pixel electrode PE to form the emission area. For example, the opening of the bank 333 can overlap a portion of the pixel electrode PE. The bank 333 can be formed of an inorganic insulating material such as silicon nitride (SiNx) and silicon oxide (SiOx), or an organic insulating material such as benzocyclobutene resin, acrylic resin, or imide resin, but embodiments of the present disclosure are not limited thereto. Further, a spacer can be further disposed on the bank 333.

The intermediate layer EL of the light emitting element ED can be disposed on a portion of the pixel electrode PE and the bank 333. The common electrode CE can be disposed on the intermediate layer EL.

Referring to FIG. 3, the encapsulation unit can be disposed on the light emitting element forming unit and can be positioned on the common electrode CE. The encapsulation unit can include the encapsulation layer 200 formed on the common electrode CE.

The encapsulation layer 200 can prevent moisture or oxygen from penetrating into the light emitting element ED. For example, the encapsulation layer 200 can prevent moisture or oxygen from penetrating into the organic material included in the intermediate layer EL of the light emitting element ED. Here, the encapsulation layer 200 can be formed of a single layer or multiple layers, but embodiments of the present disclosure are not limited thereto.

Referring to FIG. 3, e.g., the encapsulation layer 200 can include a first encapsulation layer 341, a second encapsulation layer 342, and a third encapsulation layer 343. For example, the first encapsulation layer 341 and the third encapsulation layer 343 can include an inorganic layer, and the second encapsulation layer 342 can include an organic layer.

The first encapsulation layer 341 can be disposed on the cathode electrode CE and be disposed closest to the light emitting element ED. The first encapsulation layer 341 can be formed of an inorganic insulating material capable of low temperature deposition. For example, the first encapsulation layer 341 can be silicon nitride (SiNx), silicon oxide (SiOx), silicon oxynitride (SiOxNy), or aluminum oxide (AlOx). Since the first encapsulation layer 341 is deposited in a low-temperature atmosphere, the first encapsulation layer 510 can prevent the intermediate layer EL including an organic material vulnerable to a high-temperature atmosphere from being damaged during the deposition process.

The second encapsulation layer 342 can be formed with an area smaller than that of the first encapsulation layer 341. In this case, the second encapsulation layer 342 can be formed to expose two opposite ends of the first encapsulation layer 341. The second encapsulation layer 342 can serve as a buffer to relieve stress between layers due to bending of the display device, and can also serve to enhance planarization performance. For example, the second encapsulation layer 342 can be formed of an organic insulating material such as an acrylic resin, an epoxy resin, polyimide, polyethylene, silicon oxycarbon (SiOC), or the like. For example, the second encapsulation layer 342 can be formed through an inkjet method, but embodiments of the present disclosure are not limited thereto.

The third encapsulation layer 343 can be formed on the substrate 111 on which the second encapsulation layer 342 is formed to cover the upper surface and the side surface of each of the second encapsulation layer 342 and the first encapsulation layer 341. In this case, the third encapsulation layer 343 can minimize or block external moisture or oxygen from penetrating into the first encapsulation layer 341 and the second encapsulation layer 342. For example, the third encapsulation layer 343 can be formed of an inorganic insulating material such as silicon nitride (SiNx), silicon oxide (SiOx), silicon oxynitride (SiOxNy), or aluminum oxide (AlOx), but embodiments of the present disclosure are not limited thereto.

The display panel 110 according to embodiments of the present disclosure can include a touch sensor. In this case, the display panel 110 according to embodiments of the present disclosure can include a touch sensor layer 210 formed on the encapsulation layer 200.

Referring to FIG. 3, the touch sensor layer 210 can include a plurality of touch electrodes TE, and can include a sensor metal TSM and a bridge metal BRG to form the plurality of touch electrodes TE. In embodiments of the present disclosure, the sensor metal TSM is referred to as a sensor metal layer TSM, and the bridge metal BRG is referred to as a bridge metal layer BRG.

The touch sensor layer 210 can further include insulation layers such as a sensor buffer layer 351 on the encapsulation layer 200, a sensor interlayer insulation layer 352 on the sensor buffer layer 351, and a sensor protective layer 353 on the sensor interlayer insulation layer 352. Here, the sensor buffer layer 351 can be omitted.

A bridge metal BRG can be disposed between the sensor buffer layer 351 and the sensor interlayer insulation layer 352, and the sensor metal TSM can be disposed between the sensor interlayer insulation layer 352 and the sensor protective layer 353.

The sensor buffer layer 351 can be disposed on the encapsulation layer 200. The sensor buffer layer 351 can serve to prevent damage to the encapsulation layer 200 and block interference signals to the touch electrode TE by the signals of the transistor TFT. The sensor buffer layer 351 can facilitate formation of the touch electrode TE on the encapsulation layer 200 and enhance the adhesion between the touch electrode TE and the encapsulation layer 200. The sensor buffer layer 351 can be an inorganic insulation layer. For example, the sensor buffer layer 351 can include an inorganic insulating material, such as silicon oxide (SiOx), silicon nitride (SiNX), or silicon oxynitride (SiOxNy), and can be formed of a single layer or multiple layers, but the present disclosure is not limited thereto.

Each of the plurality of touch electrodes TE can be formed of a sensor metal TSM. Each of the plurality of touch electrodes TE can be a mesh-type electrode having a plurality of openings.

The plurality of touch electrodes TE can include a first touch electrode TE1 and a second touch electrode TE2. The sensor metal TSM included in the first touch electrode TE1 can be electrically connected through the bridge metal BRG. In other words, the sensor metals TSM spaced apart from each other can be electrically connected by the bridge metal BRG to constitute one first touch electrode TE1.

The bridge metal BRG can be disposed on the sensor buffer layer 351, and the sensor interlayer insulation film 352 can be disposed on the bridge layers BRG. The sensor interlayer insulation layer 352 can be an inorganic insulation layer. For example, the sensor interlayer insulation layer 352 can be formed of silicon nitride (SiNx), silicon oxide (SiOx), silicon oxynitride (SiOxNy), titanium oxide (TiOx), or aluminum oxide (AlOx), but embodiments of the present disclosure are not limited thereto.

The sensor metal TSM can be disposed on the sensor interlayer insulation layer 352. A portion of the sensor metal TSM can be connected to the corresponding bridge metal BRG through the contact hole of the sensor interlayer insulation layer 352.

Referring to FIG. 3, the sensor metal TSM and the bridge metal BRG can be disposed not to overlap the light emitting element ED. The sensor metal TSM and the bridge metal BRG can overlap the bank 334.

The plurality of sensor metals TSM can configure so that one touch electrode and can be disposed in a mesh form and electrically connected. A portion of the sensor metal TSM and another portion of the sensor metal TSM can be electrically connected through the bridge metal BRG to constitute one touch electrode TE.

The sensor protective layer 353 can be disposed while covering the sensor metal TSM and the bridge metal BRG. The sensor protective layer 353 can be an organic insulation layer. Such an organic insulation layer can be the same material as the above-described planarization layers 331 and 332, for example. The organic insulation layer can be formed of a material different from that of the second encapsulation layer 342. For example, the sensor protective layer 353 can be formed of a photocurable organic material, such as an acrylic material, a polyimide material, or a siloxane material, but embodiments of the present disclosure are not limited thereto.

The display panel 110 according to embodiments of the present disclosure can include a color filter. In this case, the display panel 110 according to embodiments of the present disclosure can include a color filter layer 360 formed on the encapsulation layer 20.

In the structure of FIG. 3, a color filter layer 360 can be disposed on the encapsulation layer 200. For this structure, the display panel 110 can include a color filter buffer layer 361 and a color filter 363 disposed on the touch sensor layer 210. Hereinafter, for convenience of description, the structure in which the color filter layer 360 is disposed on the encapsulation layer 200 is also referred to as a color filter on encapsulation layer (COE) structure.

A color filter buffer layer 361 can be disposed on the touch sensor layer 210. The color filter buffer layer 361 can be disposed on the sensor protective layer 353. The color filter buffer layer 361 can protect the touch sensor layer 210 from being damaged in the process of forming the color filter 363 and the black matrix 362 disposed on the touch sensor layer 210. Further, the color filter buffer layer 361 can prevent penetration of moisture or oxygen from the outside to protect the touch sensor layer 210 from deteriorating. The color filter buffer layer 361 can be formed of an inorganic insulating material having excellent barrier properties. For example, the color filter buffer layer 361 can be formed of silicon oxide (SiOx), silicon nitride (SiNx), aluminum oxide (AlOx), silicon oxynitride (SiOxNy), or the like, but embodiments of the present disclosure are not limited thereto. Further, the color filter buffer layer 361 can compensate for the decrease in adhesion between the color filter 363 and the black matrix 362 and the touch sensor layer 210. In other words, the color filter buffer layer 361 can be disposed on the touch sensor layer 210 so that the color filter 363, the black matrix 362, and the touch sensor layer 210 can be bonded to each other.

A color filter 363 and a black matrix 362 can be disposed on the color filter buffer layer 361. The color filter 363 and the black matrix 362 can function as an anti-reflection layer that absorbs external light while maintaining a high luminance of light emitted from the light emitting element ED to minimize a decrease in visibility and contrast ratio of the display device 100 due to external light. The color filter 363 is disposed on the color filter buffer layer 361 to correspond to the subpixel SP emitting light of each color. The color filter 363 can be independently disposed to correspond to each subpixel SP. The black matrix 362 can be disposed on the color filter buffer layer 361 to partition the color filter 363. The black matrix 362 can be disposed along the boundary of the subpixel SP. The black matrix 362 can be disposed to overlap the bank 333. Accordingly, color mixing between the subpixels SP can be minimized.

An overcoating layer 364 can be disposed to cover the color filter 363 and the black matrix 362. The overcoating layer 364 can be an organic insulation layer for planarizing and protecting upper portions of the color filter 363 and the black matrix 362. The overcoating layer 364 can be formed of a transparent resin such as an acrylic resin, a silicone resin, a polyester resin, or an epoxy resin, but embodiments of the present disclosure are not limited thereto.

The overcoating layer 364 can completely remove or compensate a step formed by the color filter 363 and the black matrix 362 disposed in each subpixel SP area. For example, the upper surface of the overcoating layer 364 can be rendered to have a flat plane by removing the stepped area through a chemical mechanical polishing (CMP) process.

For example, the upper surface of the overcoating layer 364 facing the substrate 111 can be a flat plane. The upper surface of the overcoating layer 364 can be parallel to the upper surface of the substrate 111. By enhancing the flatness of the overcoating layer 364, it is possible to mitigate a decrease in transmittance due to a fine step on the upper surface of the overcoating layer 364.

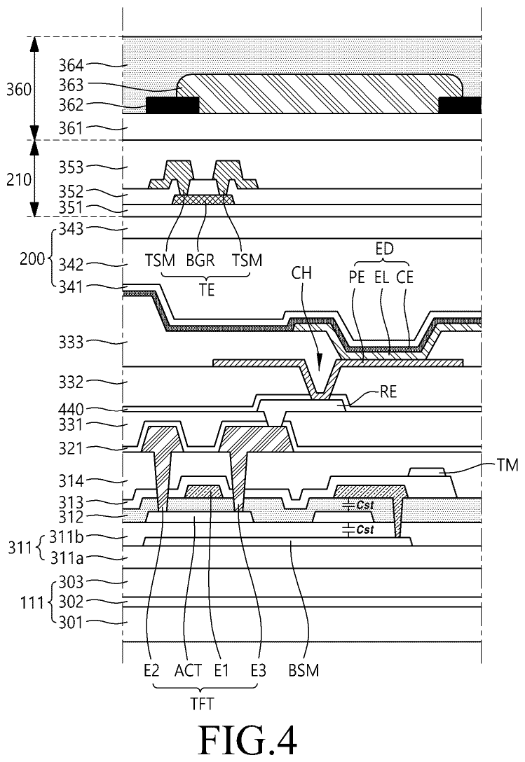

FIG. 4 is another example cross-sectional view illustrating a subpixel SP area of a display device 100 according to embodiments of the present disclosure. What is identical or similar to those described with reference to FIGS. 1 to 3 is omitted from the following description or briefly described below.

The cross section of the subpixel SP area illustrated in FIG. 4 is different from the cross section of the subpixel SP area illustrated in FIG. 3 in that it has a planarization auxiliary layer 440, and are substantially the same in the other configuration. Thus, no duplicate description is presented below.

Referring to FIG. 4, a planarization auxiliary layer 440 can be disposed on the first planarization layer 331 and the relay electrode RE. The planarization auxiliary layer 440 can include an inorganic insulating material. For example, the planarization auxiliary layer 440 can be formed of a single layer of silicon oxide (SiOx), silicon nitride (SiNx), or silicon oxynitride (SiOxNy), or multiple layers thereof, but embodiments of the present disclosure are not limited thereto.

Referring to FIG. 4, a second planarization layer 332 can be disposed on the planarization auxiliary layer 440. In this case, the second planarization layer 332 can be not contacting the relay electrode RE. In other words, the second planarization layer 332 and the relay electrode RE can be distinguished from each other by the planarization auxiliary layer 440.

Referring to FIG. 4, the second planarization layer 322 can completely remove or compensate the step formed by various components such as the transistor TFT, the storage capacitor Cst, the relay electrode RE, and various signal lines disposed in each subpixel SP area. The upper surface of the second planarization layer 332 can have a flat plane by removing a stepped area through a chemical mechanical polishing (CMP) process.

For example, the upper surface of the second planarization layer 332 facing the substrate 111 can be a flat plane. The upper surface of the second planarization layer 332 can be parallel to the upper surface of the substrate 111. In particular, the upper surface of the second planarization layer 332 overlapping the area where the relay electrode RE is disposed can have the same plane as the upper surface of the second planarization layer 332 in the area where the relay electrode RE is not disposed. In other words, the upper periphery of the contact hole CH and the upper surface of the second planarization layer 332 provided in the auxiliary planarization layer 440 and the second planarization layer 332 for connecting the relay electrode RE and the pixel electrode PE of the light emitting element ED can have a flat plane. Therefore, the flatness of the second planarization layer 332 is enhanced, so that the lower step of the area where the pixel electrode PE of the light emitting element ED is disposed can be completely removed, thereby enhancing the flatness of the pixel electrode PE. As the flatness of the second planarization layer 332 and the pixel electrode PE is enhanced, reflection visibility and rainbow mura can be mitigated.

Referring to FIG. 4, when the planarization auxiliary layer 440 is disposed on the first planarization layer 331 and the relay electrode RE, a discontinuity is formed in the planarization auxiliary layer 440 at a location where the contact hole CH is positioned to overlap the relay electrode RE. The discontinuity in the planarization auxiliary layer 440 exposes a portion of the relay electrode RE and provides contact of the pixel electrode PE with the relay electrode RE.

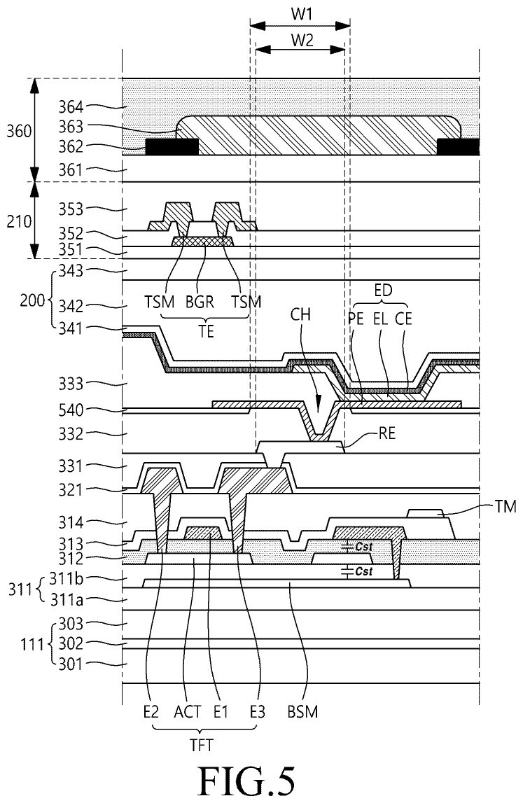

FIG. 5 is another example cross-sectional view illustrating a subpixel SP area of a display device 100 according to embodiments of the present disclosure. Those identical or similar to what has been described with reference to FIGS. 1 to 4 are omitted from the following description or are briefly described.

The cross section of the subpixel SP area illustrated in FIG. 5 is different from the cross section of the subpixel SP area illustrated in FIG. 3 in that it has a planarization auxiliary layer 540, and are substantially the same in the other configuration. Thus, no duplicate description is presented below.

Referring to FIG. 5, a planarization auxiliary layer 540 can be disposed on the second planarization layer 332. The planarization auxiliary layer 540 can include an inorganic insulating material. For example, the planarization auxiliary layer 540 can be formed of a single layer of silicon oxide (SiOx), silicon nitride (SiNx), or silicon oxynitride (SiOxNy), or multiple layers thereof, but embodiments of the present disclosure are not limited thereto.

Referring to FIG. 5, the planarization auxiliary layer 540 can be disposed not to overlap the relay electrode RE. For example, the planarization auxiliary layer 540 can be not disposed in an area overlapping the area where the relay electrode RE is disposed. Further, the planarization auxiliary layer 540 can be disposed in an area that does not overlap the area where the relay electrode RE is disposed.

Referring to FIG. 5, in a cross sectional view, the planarization auxiliary layer 540 can be disposed to be spaced apart from the relay electrode RE. In other words, the width W1 of the area where the planarization auxiliary layer 540 is not disposed can be larger than the width W2 of the area where the relay electrode RE is disposed.

Referring to FIG. 5, the second planarization layer 332 can completely remove the step formed by various components such as the transistor TFT, the storage capacitor Cst, the relay electrode RE, and various signal lines disposed in each subpixel SP area.

The second planarization layer 332 can be disposed in the area where the planarization auxiliary layer 540 is not disposed. For example, the upper surface of the auxiliary planarization layer 540 disposed on the second planarization layer 332 and the upper surface of the second planarization layer 332 in the area where the auxiliary planarization layer 540 is not disposed can have a flat plane. In other words, the upper surface of the planarization auxiliary layer 540 and the upper surface of the second planarization layer 332, in the area where the planarization auxiliary layer 540 is not disposed, can have flat planes extending from each other.

The upper surface of the planarization auxiliary layer 540 and the upper surface of the second planarization layer 332 can have a flat plane by removing a stepped area through a chemical mechanical polishing (CMP) process.

For example, the upper surface of the planarization auxiliary layer 540 and the upper surface of the second planarization layer 332 facing the substrate 111 can be flat planes. The upper surface of the planarization auxiliary layer 540 and the upper surface of the second planarization layer 332 can be parallel to the upper surface of the substrate 111. In particular, the upper surface of the second planarization layer 332 overlapping the area where the relay electrode RE is disposed can have the same plane as the upper surface of the auxiliary planarization layer 540 in the area where the relay electrode RE is not disposed. In other words, the upper periphery of the contact hole CH provided in the second planarization layer 332 for connecting the relay electrode RE and the pixel electrode PE of the light emitting element ED and the upper surface of the auxiliary planarization layer 540 can have a flat plane. Therefore, the flatness of the upper surface including the planarization auxiliary layer 540 and the second planarization layer 332 is enhanced, so that the lower step of the area where the pixel electrode PE of the light emitting element ED is disposed can be completely removed or compensated, thereby enhancing the flatness of the pixel electrode PE. Since the flatness of the upper surface including the planarization auxiliary layer 540 and the second planarization layer 332 and the pixel electrode PE are enhanced, reflection visibility and rainbow mura can be mitigated.

Referring to FIG. 5, the upper surface of the planarization auxiliary layer 540 and the upper surface of the second planarization layer 332 facing the substrate 111 can be flat planes and be coplanar. Also, the pixel electrode PE can overlap the upper surface of the planarization auxiliary layer 540 and the upper surface of the second planarization layer 332. In this instance, the pixel electrode PE overlaps a contact position between an edge of the upper surface of the planarization auxiliary layer 540 and an edge of the upper surface of the second planarization layer 332. When the upper surface of the planarization auxiliary layer 540 and the upper surface of the second planarization layer 332 are flat planes and are coplanar, a bottom surface of the pixel electrode PE can be flat and contact the upper surface of the planarization auxiliary layer 540 and the upper surface of the second planarization layer 332.

Referring to FIG. 5, when the planarization auxiliary layer 540 is disposed on the second planarization layer 332, a discontinuity is formed in the planarization auxiliary layer 540 at a location where the relay electrode RE is located. The discontinuity in the planarization auxiliary layer 540 exposes the entire relay electrode RE which provides the contact hole CH to enable contact of the pixel electrode PE with the relay electrode RE.

With reference to FIGS. 4 and 5, a planarization auxiliary layer can be located on the second planarization layer 332 or the second planarization layer 332 can be located on the planarization auxiliary layer. In various embodiments of the present disclosure, there can be a plurality of planarization auxiliary layers, so that the second planarization layer 332 can be located on a first planarization auxiliary layer and a second planarization auxiliary layer can be located on the second planarization layer 332. In such an embodiment of the present disclosure, the second planarization layer 332 can be located between the first planarization auxiliary layer (e.g., 440) and the second planarization auxiliary layer (e.g., 540). In various embodiments of the present disclosure, at least one of the first planarization auxiliary layer (e.g., 440) and the second planarization auxiliary layer (e.g., 540) can include an inorganic material, and the second planarization layer 332 can include an organic material.

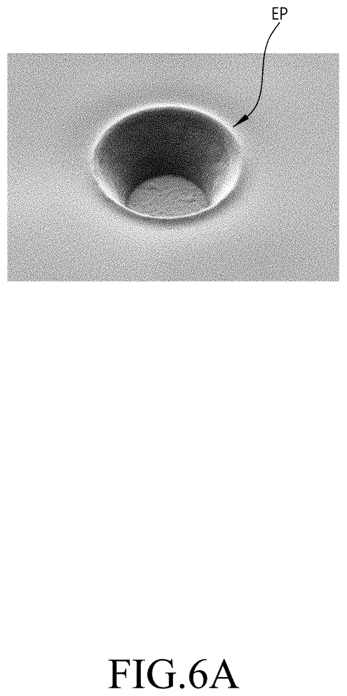

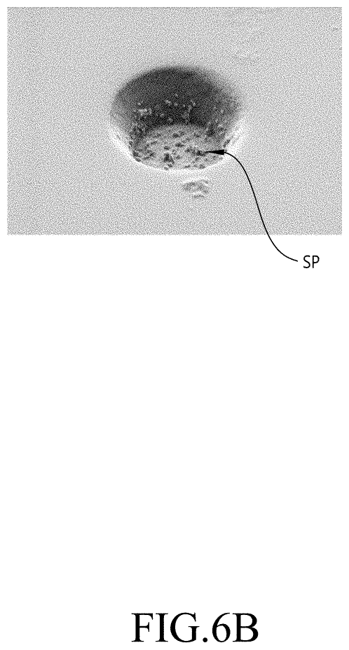

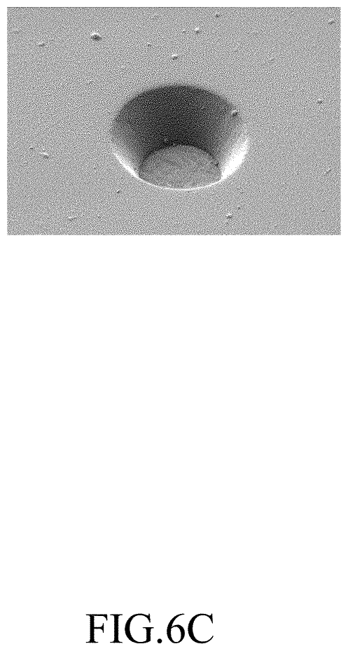

FIGS. 6A to 6C are example views illustrating a contact hole area of a display device 100 according to embodiments of the present disclosure. Those identical or similar to what has been described with reference to FIGS. 1 to 5 are omitted from the following description or are briefly described.

FIG. 6A illustrates a contact hole area of comparative example 1 where a planarization process is not performed, FIG. 6B illustrates a contact hole area of comparative example 2 where a CMP process is performed on the contact hole of comparative example 1, and FIG. 6C illustrates a contact hole area where a CMP process is performed in the structure according to embodiments of the present disclosure.

Referring to FIG. 6A, in the case of the contact hole area where the planarization process is not performed, it can be identified that an edge pattern (EP) is formed around the contact hole to cause a step. Referring to FIG. 6B, it can be identified that slurry particles SP used in the CMP process are generated inside the contact hole after performing the CMP process, which is a planarization process. Referring to FIG. 6C, it can be identified that slurry particles are not generated inside the contact hole even when the CMP process is performed in the structure according to the embodiments of the present disclosure. In various embodiments of the present disclosure, the edge pattern (EP) can be formed at or around a peripheral edge of the contact hole. In one example, the edge pattern (EP) can be formed as an annular pattern around the contact hole and can have a certain height from a flat plane of the second planarization layer. The certain height of the edge pattern (EP) can be different from a depth of the contact hole, and in one example, the certain height of the edge pattern (EP) can be less than the depth of the contact hole.

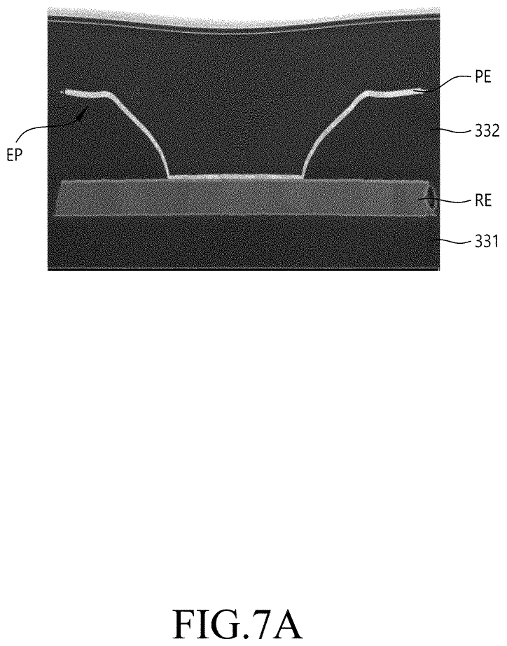

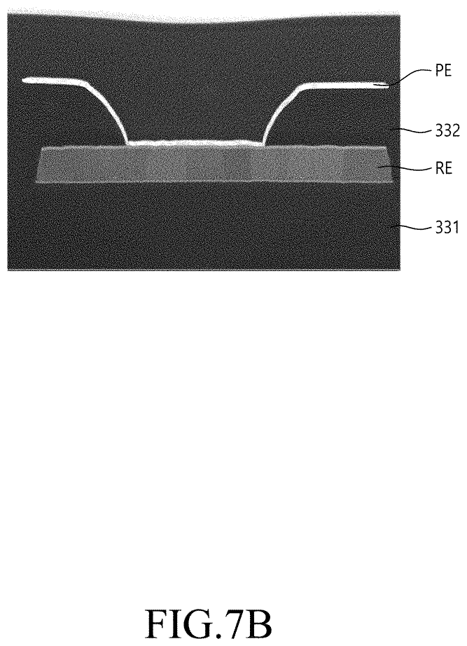

FIGS. 7A and 7B are example cross-sectional views illustrating a contact hole area of a display device 100 according to embodiments of the present disclosure. In the following description, those identical or similar to what has been described in connection with FIGS. 1 to 6C are briefly described.

FIG. 7A is a cross-sectional view illustrating a contact hole area of comparative example 1 where a planarization process is not performed, and FIG. 7B is a cross-sectional view illustrating a contact hole area where a CMP process is performed in the structure according to embodiments of the present disclosure.

Referring to FIG. 7A, in the case of the contact hole area where the planarization process is not performed, it can be identified that an edge pattern (EP) is formed around the contact hole to cause a step. Referring to FIG. 7B, after the CMP process is performed in the structure according to embodiments of the present disclosure, a step is removed around the contact hole to enhance the flatness of the second planarization layer 332 and the pixel electrode PE.

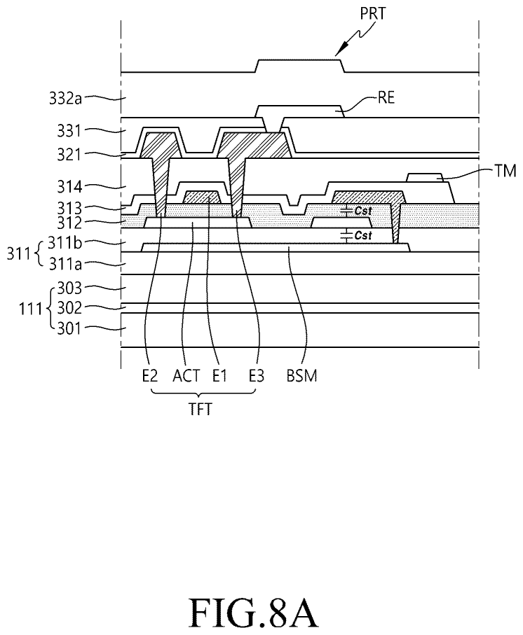

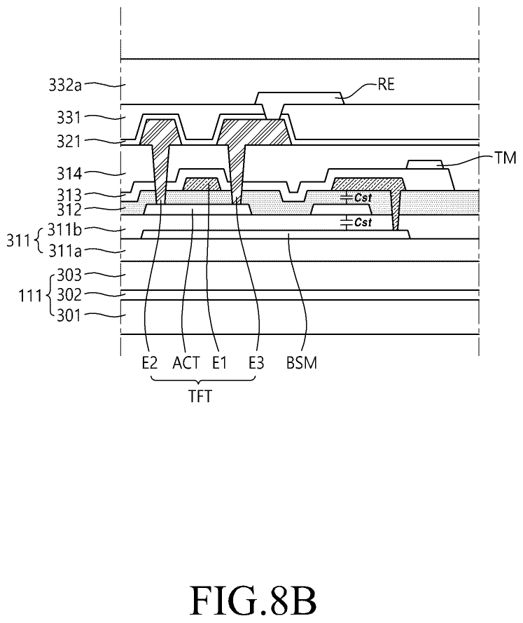

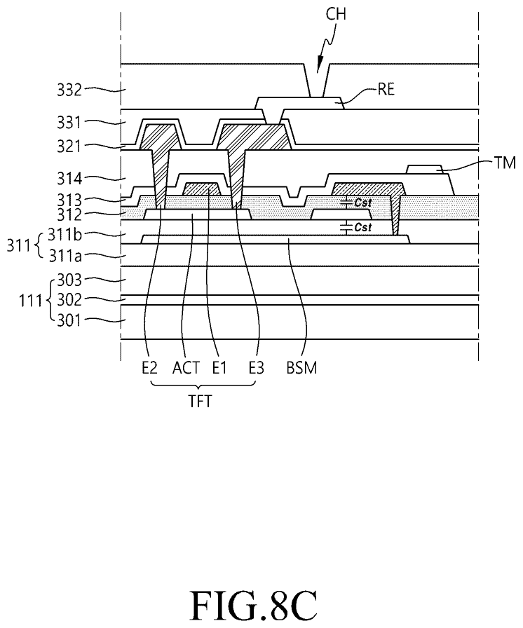

FIGS. 8A to 8C are example views illustrating a process for manufacturing the display device 100 illustrated in FIG. 3. Those identical or similar to what has been described with reference to FIGS. 1 to 7B are omitted from the following description or are briefly described.

In the display device 100 according to embodiments of the present disclosure, a solution is to form the relay electrode RE on the first planarization layer 331 and then enhance the flatness of the first planarization layer 331 and the second planarization layer 332 formed on the relay electrode RE. Thus, the description of the process focuses thereon.

Referring to FIG. 8A, a contact hole can be formed in the protective layer 321 and the first planarization layer 331 so that a portion of the upper surface of the source electrode E3 is exposed. A relay electrode RE can be formed in the contact hole and the first planarization layer 331. A second planarization material layer 332a can be formed on the first planarization layer 331 to cover the relay electrode RE. In this case, the second planarization material layer 332a can include a protruding pattern PRT where a step is formed in an area overlapping the relay electrode RE.

Referring to FIG. 8B, the second planarization material layer 332a can be planarized to form a second planarization material layer 332a having a flat upper surface. The upper surface of the second planarization material layer 332a can have a flat plane by a planarization process. The planarization process can include a CMP process. For example, the upper surface of the second planarization material layer 332a can have a flat plane by removing a stepped area through a CMP process.

Referring to FIG. 8C, a contact hole CH can be formed in the second planarization layer 332 to expose a portion of the upper surface of the relay electrode RE. After the upper surface of the second planarization layer 332 is planarized by the CMP process, the contact hole CH of the second planarization layer 332 is formed to prevent slurry particles SP from being generated by the CMP process inside the contact hole CH.

A light emitting element ED, an encapsulation layer 200, a touch sensor layer 210, and a color filter layer 360 can be sequentially formed thereafter. Here, the touch sensor layer 210 can be omitted. When the color filter layer 360 is formed, the upper surface of the overcoat layer 364 can have a flat plane by removing a stepped area through a CMP process.

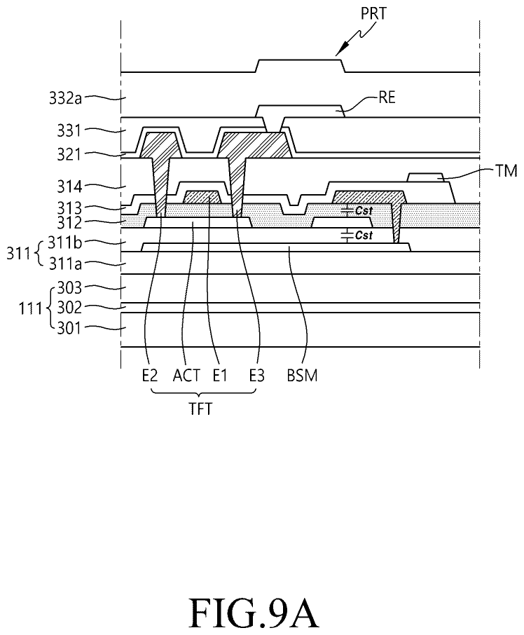

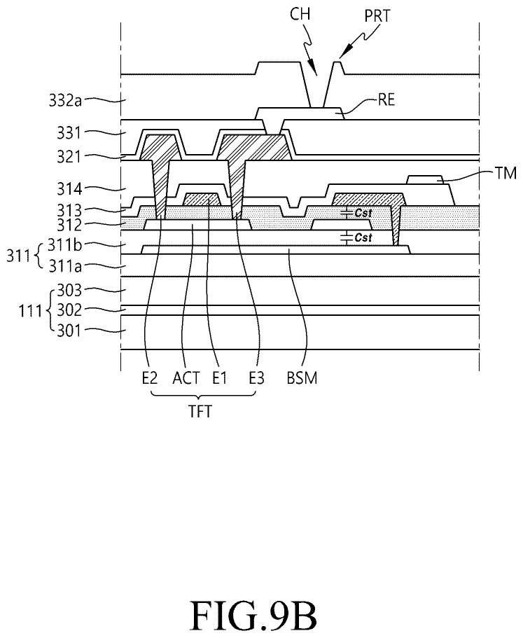

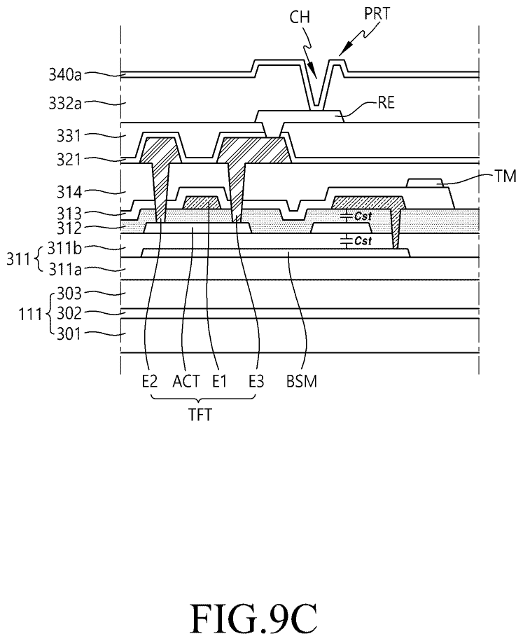

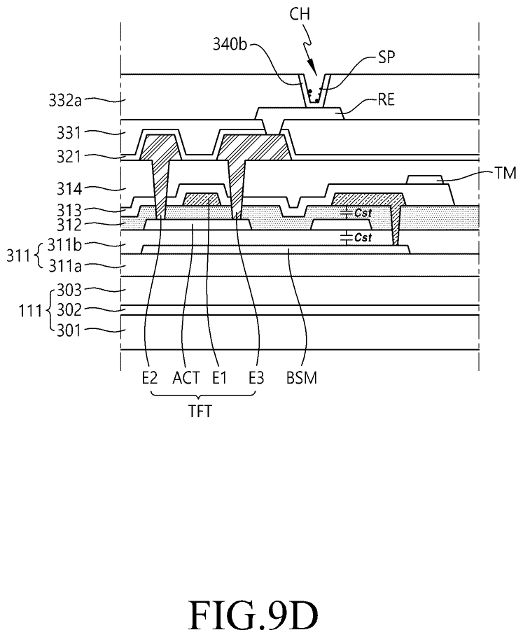

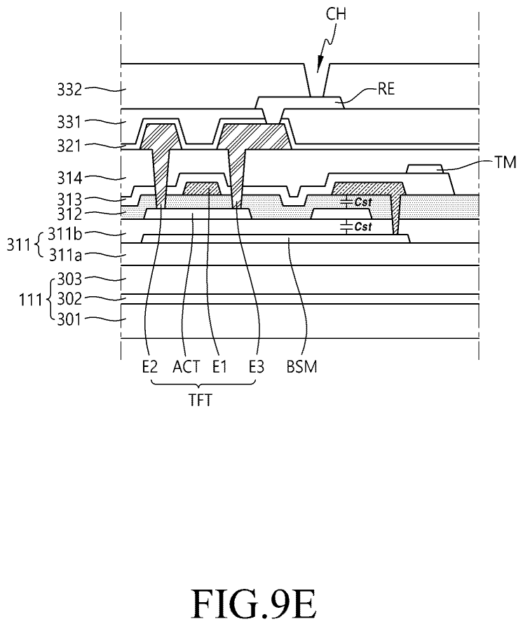

FIGS. 9A to 9E are other example views illustrating a process for manufacturing the display device 100 illustrated in FIG. 3. What is identical or similar to those described in connection with FIGS. 1 to 8C can be omitted or briefly described below.

Referring to FIG. 9A, a contact hole can be formed in the protective layer 321 and the first planarization layer 331 so that a portion of the upper surface of the source electrode E3 is exposed. A relay electrode RE can be formed in the contact hole and the first planarization layer 331. A second planarization material layer 332a can be formed on the first planarization layer 331 to cover the relay electrode RE. In this case, the second planarization material layer 332a can include a protruding pattern PRT where a step is formed in an area overlapping the relay electrode RE.

Referring to FIG. 9B, a contact hole CH can be formed in the protruding pattern PRT of the second planarization material layer 332a so that a portion of the upper surface of the relay electrode RE is exposed.

Referring to FIG. 9C, a planarization auxiliary material layer 340a can be formed on the second planarization material layer 332a and the relay electrode RE. The planarization auxiliary material layer 340a can include an inorganic insulating material. For example, the planarization auxiliary material layer (340a) can be formed of a single layer of silicon oxide (SiOx), silicon nitride (SiNx), or silicon oxynitride (SiOxNy), or multiple layers thereof.

Referring to FIG. 9D, a planarization process can be performed to remove the planarization auxiliary material layer 340a formed on the upper surface of the second planarization material layer 332a, and to planarize the protruding pattern PRT of the second planarization material layer 332a. In this case, slurry particles SP generated in the CMP process can be accumulated on the planarization auxiliary pattern 340b and the planarization auxiliary pattern 340b in the contact hole CH.

Referring to FIG. 9E, the second planarization layer 332 including the contact hole CH can be formed by removing the planarization auxiliary pattern 340b and the slurry particles SP in the contact hole CH. The planarization auxiliary pattern 340b and the slurry particles SP can be removed simultaneously or sequentially.

When the slurry particles SP and the planarization auxiliary pattern 340b include the same material, wet etching can be performed to remove the slurry particles SP and the planarization auxiliary pattern 340b.

Meanwhile, when the slurry particles SP and the planarization auxiliary pattern 340b include different materials, the slurry particles SP can be removed by wet etching, and then the planarization auxiliary pattern 340b can be removed through dry etching.

A light emitting element ED, an encapsulation layer 200, a touch sensor layer 210, and a color filter layer 360 can be sequentially formed thereafter. Here, the touch sensor layer 210 can be omitted. When the color filter layer 360 is formed, the upper surface of the overcoat layer 364 can have a flat plane by removing a stepped area through a CMP process.

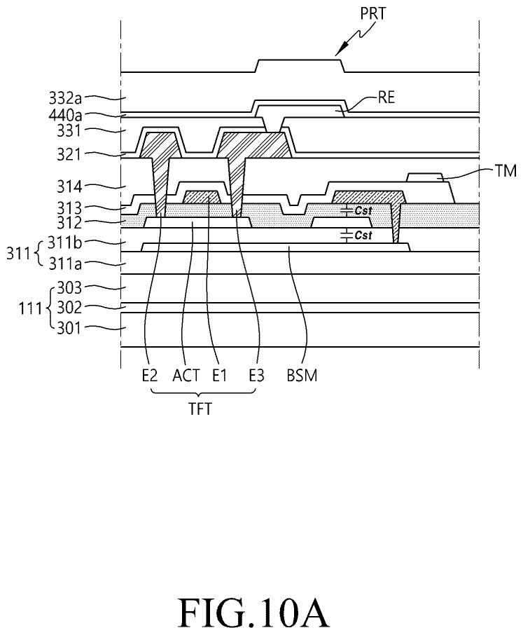

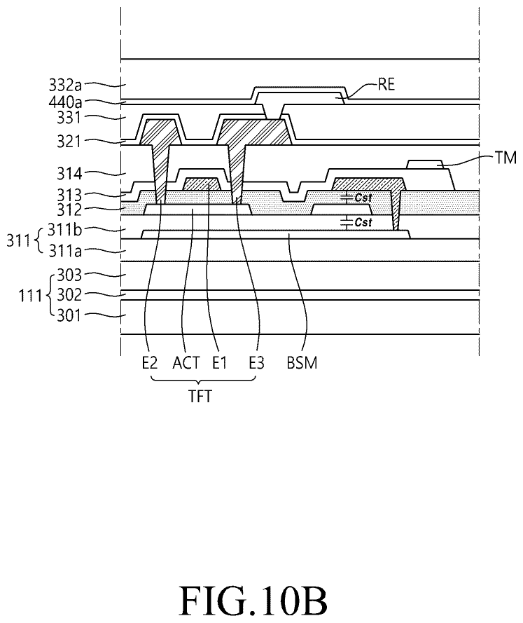

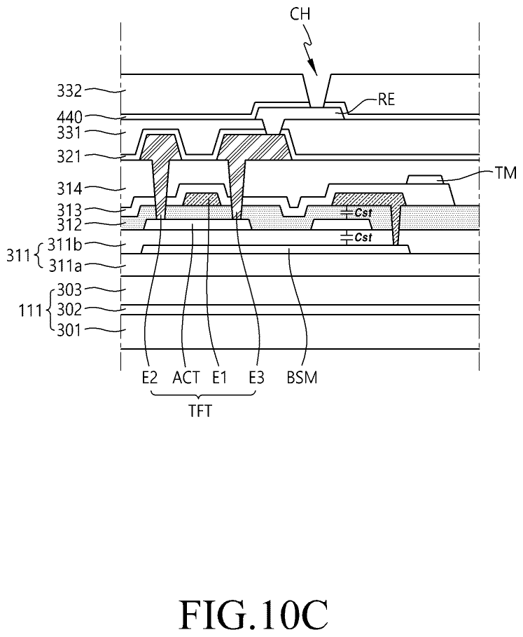

FIGS. 10A to 10C are example views illustrating a process for manufacturing the display device 100 illustrated in FIG. 4. What is identical or similar to those described in connection with FIGS. 1 to 9E can be omitted or briefly described below.

Referring to FIG. 10A, a contact hole can be formed in the protective layer 321 and the first planarization layer 331 so that a portion of the upper surface of the source electrode E3 is exposed. A relay electrode RE can be formed in the contact hole and the first planarization layer 331. A planarization auxiliary material layer 440a can be formed on the first planarization layer 331 to cover the relay electrode RE. A second planarization material layer 332a can be formed on the planarization auxiliary material layer 440a. In this case, the second planarization material layer 332a can include a protruding pattern PRT where a step is formed in an area overlapping the relay electrode RE.

Referring to FIG. 10B, the second planarization material layer 332a can be planarized to form a second planarization material layer 332a having a flat upper surface. The upper surface of the second planarization material layer 332a can have a flat plane by a planarization process. The planarization process can include a CMP process. For example, the upper surface of the second planarization material layer 332a can have a flat plane by removing a stepped area through a CMP process.

Referring to FIG. 10C, a contact hole CH can be formed in the second planarization layer 332 and the auxiliary planarization layer 440 to expose a portion of the upper surface of the relay electrode RE. After the upper surface of the second planarization layer 332 is planarized by the CMP process, the contact hole CH of the second planarization layer 332 is formed to prevent slurry particles SP from being generated by the CMP process inside the contact hole CH.

A light emitting element ED, an encapsulation layer 200, a touch sensor layer 210, and a color filter layer 360 can be sequentially formed thereafter. Here, the touch sensor layer 210 can be omitted. When the color filter layer 360 is formed, the upper surface of the overcoat layer 364 can have a flat plane by removing a stepped area through a CMP process.

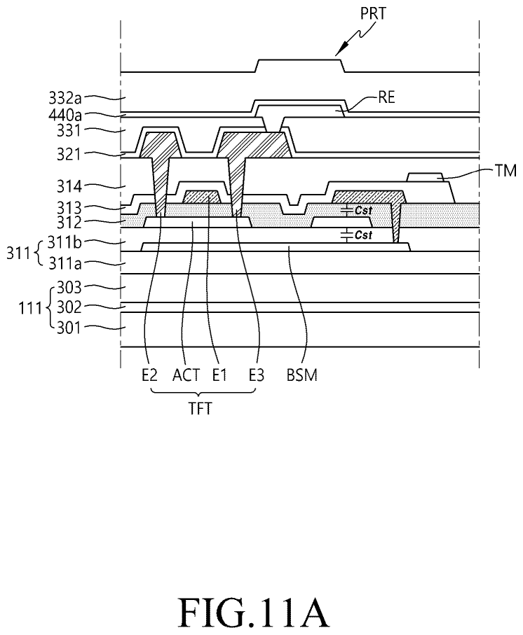

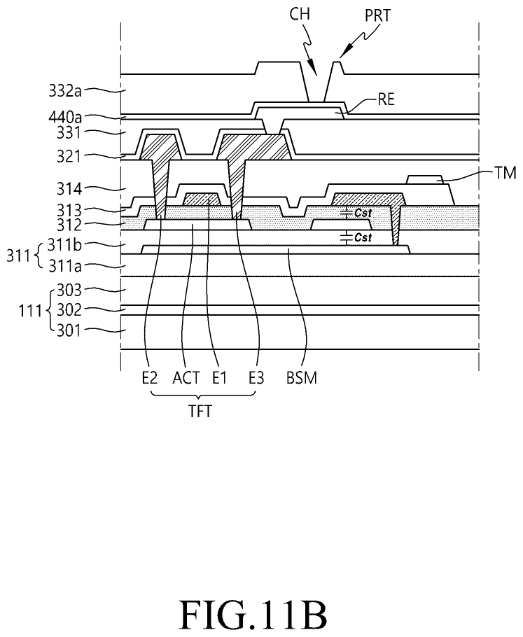

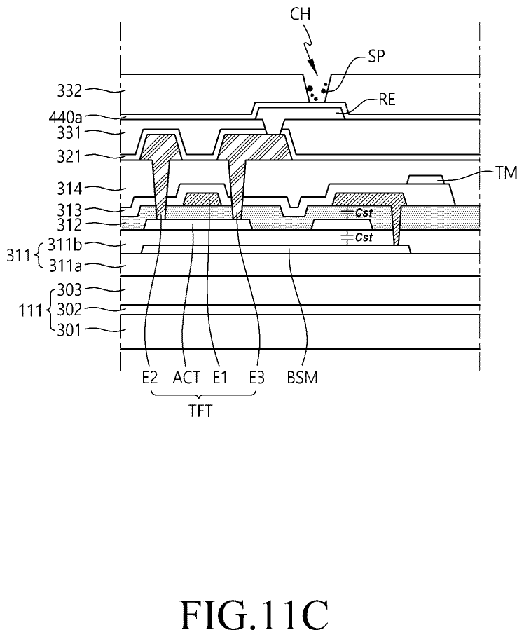

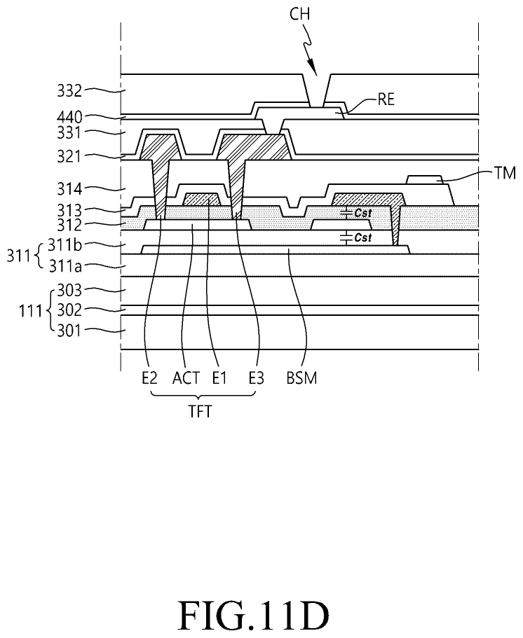

FIGS. 11A to 11D are other example views illustrating a process for manufacturing the display device 100 illustrated in FIG. 4. What is identical or similar to those described in connection with FIGS. 1 to 10C can be omitted or briefly described below.

Referring to FIG. 11A, a contact hole can be formed in the protective layer 321 and the first planarization layer 331 so that a portion of the upper surface of the source electrode E3 is exposed. A relay electrode RE can be formed in the contact hole and the first planarization layer 331. A planarization auxiliary material layer 440a can be formed on the first planarization layer 331 to cover the relay electrode RE. A second planarization material layer 332a can be formed on the planarization auxiliary material layer 440a. In this case, the second planarization material layer 332a can include a protruding pattern PRT where a step is formed in an area overlapping the relay electrode RE.

Referring to FIG. 11B, a contact hole CH can be formed in the protruding pattern PRT of the second planarization material layer 332a so that a portion of the upper surface of the auxiliary planarization material layer 440a is exposed.

Referring to FIG. 11C, a planarization process can be performed to planarize the protruding pattern PRT of the second planarization material layer 332a. In this case, slurry particles SP generated in the CMP process can be accumulated in the contact hole CH.

Referring to FIG. 11D, the slurry particles SP and the planarization auxiliary material layer 440a in the contact hole CH can be removed to form a second planarization layer 332 and a planarization auxiliary layer 440 including the contact hole CH. The slurry particles SP and the planarization auxiliary material layer 440a can be removed simultaneously or sequentially.

When the slurry particles SP and the planarization auxiliary material layer 440a include the same material, the slurry particles SP and the planarization auxiliary material layer 440a can be removed by wet etching.

Meanwhile, when the slurry particles SP and the planarization auxiliary material layer 440a include different materials, the slurry particles SP can be removed by wet etching, and then the planarization auxiliary material layer 440a can be removed by dry etching.

A light emitting element ED, an encapsulation layer 200, a touch sensor layer 210, and a color filter layer 360 can be sequentially formed thereafter. Here, the touch sensor layer 210 can be omitted. When the color filter layer 360 is formed, the upper surface of the overcoat layer 364 can have a flat plane by removing a stepped area through a CMP process.

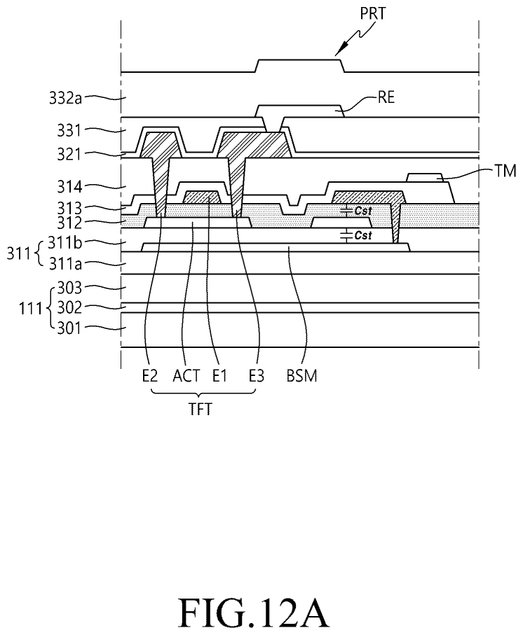

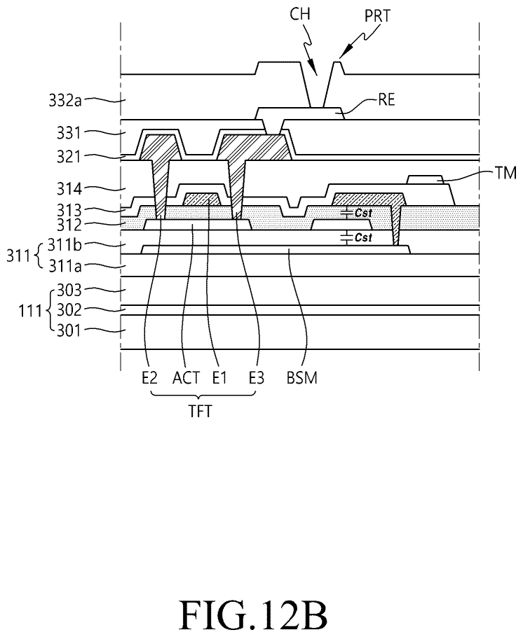

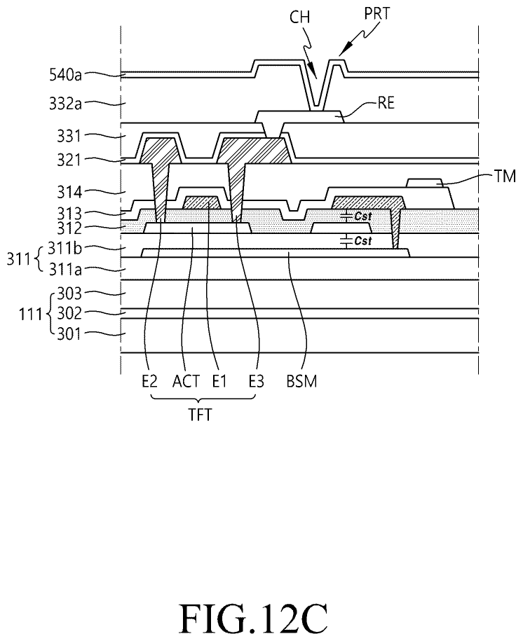

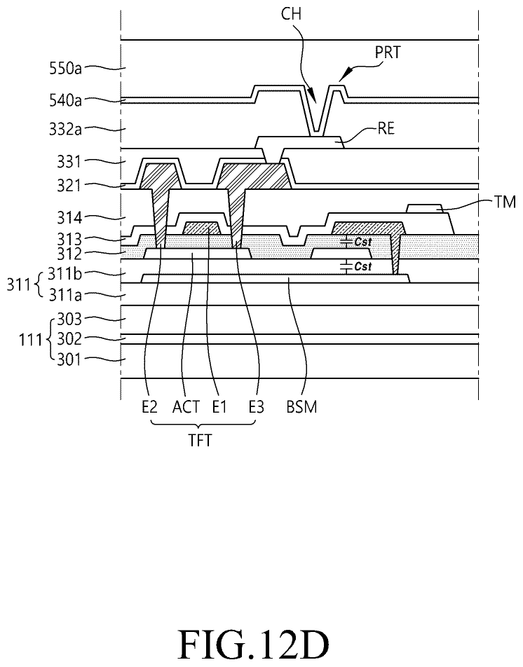

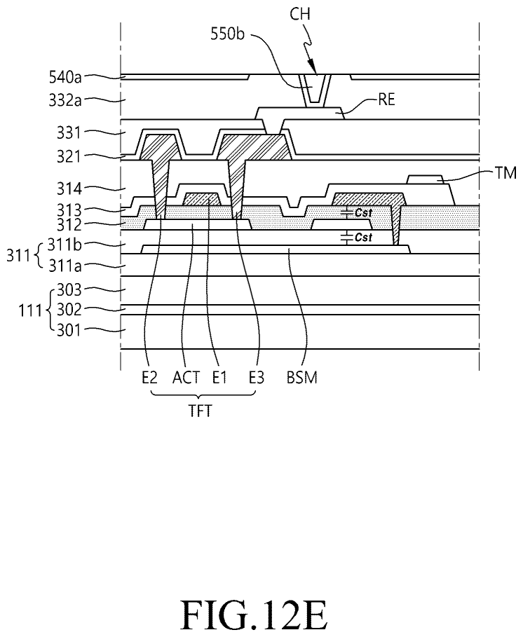

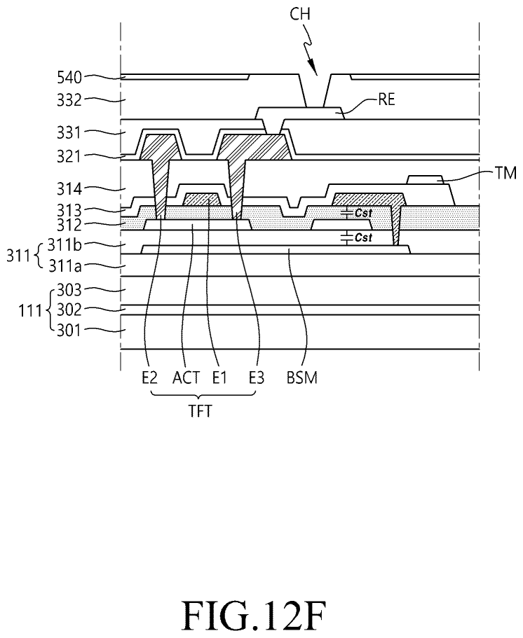

FIGS. 12A to 12F are example views illustrating a process for manufacturing the display device 100 illustrated in FIG. 5. In the following description, those identical or similar to what has been described in connection with FIGS. 1 to 11D are briefly described.

Referring to FIG. 12A, a contact hole can be formed in the protective layer 321 and the first planarization layer 331 so that a portion of the upper surface of the source electrode E3 is exposed. A relay electrode RE can be formed in the contact hole and the first planarization layer 331. A second planarization material layer 332a can be formed on the first planarization layer 331 to cover the relay electrode RE. In this case, the second planarization material layer 332a can include a protruding pattern PRT where a step is formed in an area overlapping the relay electrode RE.

Referring to FIG. 12B, a contact hole CH can be formed in the protruding pattern PRT of the second planarization material layer 332a so that a portion of the upper surface of the relay electrode RE is exposed.

Referring to FIG. 12C, a planarization auxiliary material layer 540a can be formed on the second planarization material layer 332a and the relay electrode RE.

Referring to FIG. 12D, an organic material layer 550a can be formed on the planarization auxiliary material layer 540a.

Referring to FIG. 12E, the planarization process can be performed to remove the organic material layer 550a disposed on the planarization auxiliary material layer 540a, the protruding pattern PRT, and the planarization auxiliary material layer 540a disposed on the protruding pattern PRT, and to allow the upper surface of the planarization auxiliary material layer 540a and the upper surface of the second planarization material layer 332a to be the same plane. In this case, the planarization auxiliary pattern 540b and the organic material pattern 550b can remain in the contact hole CH.

Referring to FIG. 12F, the second planarization layer 332 and the planarization auxiliary layer 540 having the contact hole CH can be formed by removing the planarization auxiliary pattern 540b and the organic material pattern 550b in the contact hole CH. The planarization auxiliary pattern 540b and the organic material pattern 550b can be removed simultaneously or sequentially.

When the slurry particles SP and the planarization auxiliary pattern 540b used in the CMP process include the same material, the organic material pattern 550b can be removed through dry etching and ashing processes, and then the planarization auxiliary pattern 540b can be removed by wet etching.

Meanwhile, when the slurry particles SP and the auxiliary planarization pattern 540b used in the CMP process include different materials, the auxiliary planarization pattern 540b and the organic material pattern 550b can be removed through dry etching.

A light emitting element ED, an encapsulation layer 200, a touch sensor layer 210, and a color filter layer 360 can be sequentially formed thereafter. Here, the touch sensor layer 210 can be omitted. When the color filter layer 360 is formed, the upper surface of the overcoat layer 364 can have a flat plane by removing a stepped area through a CMP process.

Embodiments of the present disclosure described above are briefly described below.

A display device according to embodiments of the present disclosure can comprise a substrate including a subpixel, a thin film transistor disposed on the substrate, a first planarization layer positioned on the thin film transistor, a relay electrode positioned on the first planarization layer and electrically connected to the thin film transistor through a contact hole of the first planarization layer, a second planarization layer positioned on the first planarization layer and disposed to cover the relay electrode, and a light emitting element positioned on the second planarization layer and electrically connected to the relay electrode through a contact hole of the second planarization layer. An upper surface of the second planarization layer can be a flat plane and can be parallel to an upper surface of the substrate.

In the display device according to embodiments of the present disclosure, an upper surface of the second planarization layer overlapping an area where the relay electrode is disposed can be the same plane as an upper surface of the second planarization layer in an area where the relay electrode is not disposed.

The display device according to embodiments of the present disclosure can further comprise an encapsulation layer positioned on the light emitting element. The encapsulation layer can include a first encapsulation layer positioned on the light emitting element, a second encapsulation layer positioned on the first encapsulation layer, and a third encapsulation layer positioned on the second encapsulation layer. The first encapsulation layer and the third encapsulation layer can include an inorganic insulating material. The second encapsulation layer can include an organic insulating material.

The display device according to embodiments of the present disclosure can further comprise a touch sensor layer positioned on the encapsulation layer. The touch sensor layer can include a sensor buffer layer positioned on the encapsulation layer, a bridge metal positioned on the sensor buffer layer, a sensor interlayer insulation film positioned on the bridge metal, and a sensor metal positioned on the sensor interlayer insulation film and electrically connected to the bridge metal through a contact hole of the sensor interlayer insulation film.

The display device according to embodiments of the present disclosure can further comprise a color filter layer positioned on the encapsulation layer. The color filter layer can include a color filter buffer layer positioned on the encapsulation layer, a color filter positioned on the color filter buffer layer, and a black matrix partitioning the color filter, and an overcoating layer disposed to cover the color filter and the black matrix. An upper surface of the overcoating layer can be a flat plane and can be parallel to an upper surface of the substrate.

The display device according to embodiments of the present disclosure can further comprise a planarization auxiliary layer positioned on the first planarization layer and disposed to cover the relay electrode.

In the display device according to embodiments of the present disclosure, a pixel electrode of the light emitting element can be electrically connected to the relay electrode through a contact hole of the second planarization layer and the planarization auxiliary layer.

In the display device according to embodiments of the present disclosure, the second planarization layer need not contact the relay electrode.

In the display device according to embodiments of the present disclosure, the second planarization layer and the relay electrode can be spaced apart by the planarization auxiliary layer.

In the display device according to embodiments of the present disclosure, the planarization auxiliary layer can include an inorganic insulating material selected from among silicon oxide, silicon nitride, and silicon oxynitride.

The display device according to embodiments of the present disclosure can further comprise a planarization auxiliary layer positioned on the second planarization layer and disposed not to overlap the relay electrode.

In the display device according to embodiments of the present disclosure, in a cross sectional view, the planarization auxiliary layer can be spaced apart from the relay electrode.

In the display device according to embodiments of the present disclosure, in a cross sectional view, a width of an area where the planarization auxiliary layer is not disposed can be larger than a width of an area where the relay electrode is disposed.

In the display device according to embodiments of the present disclosure, an upper surface of the planarization auxiliary layer and an upper surface of the second planarization layer in an area where the planarization auxiliary layer is not disposed can include a flat plane.

In the display device according to embodiments of the present disclosure, the upper surface of the planarization auxiliary layer and the upper surface of the second planarization layer in the area where the planarization auxiliary layer is not disposed can be flat planes extending from each other.

In the display device according to embodiments of the present disclosure, an upper surface of the second planarization layer overlapping an area where the relay electrode is disposed can be the same plane as an upper surface of the planarization auxiliary layer disposed in an area where the relay electrode is not disposed.

In the display device according to embodiments of the present disclosure, a contact hole of the second planarization layer can be positioned in an area where the planarization auxiliary layer is not disposed. A pixel electrode of the light emitting element can be electrically connected to the relay electrode through the contact hole of the second planarization layer.

In the display device according to embodiments of the present disclosure, the planarization auxiliary layer can include an inorganic insulating material selected from among silicon oxide, silicon nitride, and silicon oxynitride.

In the display device according to embodiments of the present disclosure, a partial area of the second planarization layer need not include fluorine (F) and sulfur (S).

In the display device according to embodiments of the present disclosure, the partial area of the second planarization layer can be an upper peripheral area of the contact hole of the second planarization layer.

By the display device according to embodiments of the present disclosure, it can be possible to enhance the flatness of a pixel electrode by leveling the upper surface of a planarization layer formed beneath the pixel electrode.

By the display device according to embodiments of the present disclosure, it can be possible to reduce or prevent the generation of foreign objects in the planarization layer and its contact hole by incorporating a planarization auxiliary layer in the planarization layer.

By the display device according to embodiments of the present disclosure, it can be possible to enhance reflection visibility and mitigates rainbow mura by minimizing the occurrence of foreign objects during the formation of the planarization layer and contact holes.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed:

1. A display device, comprising:
a substrate including at least one subpixel;
a thin film transistor disposed on the substrate;
a first planarization layer positioned on the thin film transistor;
a relay electrode positioned on the first planarization layer and electrically connected to the thin film transistor through a contact hole of the first planarization layer;
a second planarization layer positioned on the first planarization layer and disposed to cover the relay electrode; and
a light emitting element positioned on the second planarization layer and electrically connected to the relay electrode through a contact hole of the second planarization layer,
wherein an upper surface of the second planarization layer is a flat plane and is parallel to an upper surface of the substrate.

2. The display device of claim 1, wherein an upper surface of the second planarization layer overlapping an area where the relay electrode is disposed and an upper surface of the second planarization layer in an area where the relay electrode is not disposed are coplanar.

3. The display device of claim 1, further comprising an encapsulation layer positioned on the light emitting element, wherein the encapsulation layer further includes:
a first encapsulation layer positioned on the light emitting element;
a second encapsulation layer positioned on the first encapsulation layer; and
a third encapsulation layer positioned on the second encapsulation layer,
wherein the first encapsulation layer and the third encapsulation layer include an inorganic insulating material, and
wherein the second encapsulation layer includes an organic insulating material.

4. The display device of claim 3, further comprising a touch sensor layer positioned on the encapsulation layer, wherein the touch sensor layer includes:
a sensor buffer layer positioned on the encapsulation layer;
a bridge metal positioned on the sensor buffer layer;
a sensor interlayer insulation film positioned on the bridge metal; and
a sensor metal positioned on the sensor interlayer insulation film and electrically connected to the bridge metal through a contact hole of the sensor interlayer insulation film.

5. The display device of claim 3, further comprising a color filter layer positioned on the encapsulation layer, wherein the color filter layer includes:
a color filter buffer layer positioned on the encapsulation layer;
a color filter positioned on the color filter buffer layer, and a black matrix partitioning the color filter; and
an overcoating layer disposed to cover the color filter and the black matrix, and
wherein an upper surface of the overcoating layer is a flat plane and is parallel to an upper surface of the substrate.

6. The display device of claim 1, further comprising a planarization auxiliary layer positioned on the first planarization layer and disposed to cover the relay electrode or on the second planarization layer and disposed not to overlap the relay electrode.

7. The display device of claim 6, wherein, when the planarization auxiliary layer is positioned on the first planarization layer, a pixel electrode of the light emitting element is electrically connected to the relay electrode through a contact hole of the second planarization layer and the planarization auxiliary layer.

8. The display device of claim 6, wherein, when the planarization auxiliary layer is positioned on the first planarization layer, the second planarization layer does not contact the relay electrode.

9. The display device of claim 6, wherein, when the planarization auxiliary layer is positioned on the first planarization layer, the second planarization layer and the relay electrode are spaced apart by the planarization auxiliary layer.

10. The display device of claim 6, wherein the planarization auxiliary layer includes an inorganic insulating material selected from among silicon oxide, silicon nitride, and silicon oxynitride.

11. The display device of claim 6, wherein in a cross sectional view, and when the planarization auxiliary layer is positioned on the second planarization layer, the planarization auxiliary layer is spaced apart from the relay electrode.

12. The display device of claim 11, wherein in a cross sectional view, a width of an area where the planarization auxiliary layer is not disposed is larger than a width of an area where the relay electrode is disposed.

13. The display device of claim 6, wherein, when the planarization auxiliary layer is positioned on the second planarization layer, an upper surface of the planarization auxiliary layer and an upper surface of the second planarization layer in an area where the planarization auxiliary layer is not disposed include a flat plane.

14. The display device of claim 13, wherein the upper surface of the planarization auxiliary layer and the upper surface of the second planarization layer in the area where the planarization auxiliary layer is not disposed are flat planes that are coplanar.

15. The display device of claim 6, wherein, when the planarization auxiliary layer is positioned on the second planarization layer, an upper surface of the second planarization layer overlapping an area where the relay electrode is disposed coplanar with an upper surface of the planarization auxiliary layer disposed in an area where the relay electrode is not disposed.

16. The display device of claim 6, wherein, when the planarization auxiliary layer is positioned on the second planarization layer, a contact hole of the second planarization layer is positioned in an area where the planarization auxiliary layer is not disposed, and
wherein a pixel electrode of the light emitting element is electrically connected to the relay electrode through the contact hole of the second planarization layer.

17. The display device of claim 1, wherein a partial area of a surface of the second planarization layer includes less fluorine (F) and sulfur (S) that an interior of the second planarization layer.

18. The display device of claim 17, wherein the partial area of the surface of the second planarization layer is an upper peripheral area of the contact hole of the second planarization layer.

19. A display device, comprising:
a substrate including at least one subpixel;
a thin film transistor disposed on the substrate;
a first planarization layer positioned on the thin film transistor;
a relay electrode positioned on the first planarization layer and electrically connected to the thin film transistor through a contact hole of the first planarization layer;
a second planarization layer positioned on the first planarization layer; and
a light emitting element positioned on the second planarization layer and electrically connected to the relay electrode through a contact hole of the second planarization layer,
wherein an upper surface of the second planarization layer has a polished surface that is parallel to an upper surface of the substrate.

20. The display device of claim 19, further comprising a planarization auxiliary layer positioned on at least one of the first planarization layer and the second planarization layer,
wherein the planarization auxiliary layer includes an inorganic material.
